(19) United States
(12) Patent Application Publication
(10) Pub. No.: US 2026/0006909 A1
(43) Pub. Date: Jan. 1, 2026

(54) Nanoribbon Transistors Formed from Layered Materials with Dopant for Reduced Strain

(71) Applicants: David KOHEN, Hillsboro, OR (US); Rambert NAHM, Beaverton, OR (US); Glenn A. GLASS, Portland, OR (US); Borna OBRADOVIC, Portland, OR (US); Stephen M. CEA, Hillsboro, OR (US); Matthew V. METZ, Portland, OR (US); Siddharth CHOUKSEY, Portland, OR (US); Jessica M. TORRES, Portland, OR (US); Peter WELLS, Portland, OR (US); Susmita GHOSE, Hillsboro, OR (US); Michael BABB, Portland, OR (US); Natalie BRIGGS, Hillsboro, OR (US)

(72) Inventors: David KOHEN, Hillsboro, OR (US); Rambert NAHM, Beaverton, OR (US); Glenn A. GLASS, Portland, OR (US); Borna OBRADOVIC, Portland, OR (US); Stephen M. CEA, Hillsboro, OR (US); Matthew V. METZ, Portland, OR (US); Siddharth CHOUKSEY, Portland, OR (US); Jessica M. TORRES, Portland, OR (US); Peter WELLS, Portland, OR (US); Susmita GHOSE, Hillsboro, OR (US); Michael BABB, Portland, OR (US); Natalie BRIGGS, Hillsboro, OR (US)

(21) Appl. No.: 18/755,810

(22) Filed: Jun. 27, 2024

(51) Int. Cl. H10D 84/85; H10D 84/01

(52) U.S. Cl. CPC H10D 84/856; H10D 84/0167; H10D 84/0186; H10D 84/851

(57) ABSTRACT

A dopant may included in one or more sacrificial layers, e.g., silicon layers or silicon germanium layers, used for forming nanoribbon transistors. Adding a dopant to a silicon germanium layer may cause the silicon germanium to be more stress neutral, to prevent relaxation after etching stacks of individuated nanoribbons. Alternatively, when added to one or more sacrificial layers of silicon, the doped silicon layers may counteract elastic stress from the silicon germanium layers. The dopant layers may be included at various positions in a stack of materials. The dopant layer may include one or more dopants selected from carbon, arsenic, boron, and phosphorus.

### BACKGROUND

Non-planar transistors are three-dimensional electronic devices that deviate from a traditional flat transistor design. Compared to planar transistors, non-planar transistors can provide improved control over current flow, reduced leakage, and enhanced performance, making it a key technology for smaller, faster, and more energy-efficient electronic devices. Examples of non-planar transistors include fin-shaped field-effect transistors, referred to as FinFETs, and gate-all-around (GAA) transistors. GAA transistors, also referred to as surrounding-gate transistors, have a gate material that surrounds a channel region on all sides.

In general, to form GAA transistors, alternating layers of the channel material and a sacrificial material are deposited. The layers are etched to form stacks of the channel material and sacrificial material. The sacrificial material is removed from the stack and replaced with other material, e.g., gate material. The channel material and sacrificial materials include different materials, so that the sacrificial material can be removed using selective etching. In some implementations, silicon is used for the channel material, while the sacrificial material includes germanium, or a mixture of silicon and germanium. The sacrificial material may be chosen to have a similar crystal structure to the channel material, so that monocrystalline layers of the channel material and monocrystalline layers of the sacrificial material may be formed over each other.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1A is a cross-section across a nanoribbon-based transistor showing the source, gate, and drain, according to some embodiments of the present disclosure.

FIG. 1B is a cross-section of the nanoribbon-based transistor through the plane AA′ in FIG. 1A.

FIG. 2A is a cross-section of alternating layers of a semiconductor channel material and a sacrificial material that may be used for forming nanoribbon transistors.

FIG. 2B illustrates the layers of FIG. 2A after stacks have been etched to form individuated channels for different transistors, and showing relaxing of the materials.

FIG. 3A is a cross-section of alternating layers of a semiconductor channel material and a sacrificial material with a doped top layer that may be used for forming nanoribbon transistors, according to some embodiments of the present disclosure.

FIG. 3B illustrates the layers of FIG. 3A after stacks have been etched to form individuated channels for different transistors, according to some embodiments of the present disclosure.

FIG. 4 is a top-down view of a wafer with multiple dies formed thereon, according to some embodiments of the present disclosure.

FIG. 5 is a cross-section through one of the dies of FIG. 4, illustrating a set of transistors formed from the stacks of FIG. 3B and regions outside of the active area that include the layered materials and the doped top layer, according to some embodiments of the present disclosure.

FIG. 6A is a cross-section of alternating layers of a semiconductor channel material and a doped sacrificial material that may be used for forming nanoribbon transistors, according to some embodiments of the present disclosure.

FIG. 6B illustrates the layers of FIG. 6A after stacks have been etched to form individuated channels for different transistors, according to some embodiments of the present disclosure.

FIG. 7 is a cross-section through a die that includes a set of transistors formed from the stacks of FIG. 6B and regions outside of the active area that include the layered materials of FIG. 6A, according to some embodiments of the present disclosure.

FIG. 8A is a cross-section of alternating layers of a semiconductor channel material and a doped sacrificial material that may be used for forming stacked nanoribbon transistors, according to some embodiments of the present disclosure.

FIG. 8B is a cross-section through a die that includes an active area with a set of stacked transistors formed from the layered materials of FIG. 8A and regions outside of the active area, according to some embodiments of the present disclosure.

FIG. 9A is a cross-section of alternating layers of a semiconductor channel material, layers of an undoped sacrificial material, and layers of a doped sacrificial material that may be used for forming stacked nanoribbon transistors, according to some embodiments of the present disclosure.

FIG. 9B is a cross-section through a die that includes an active area with a set of stacked transistors formed from the layered materials of FIG. 9A and regions outside of the active area, according to some embodiments of the present disclosure.

FIG. 10A is a cross-section of alternating layers of a semiconductor channel material, layers of a doped channel material, layers of an undoped sacrificial material, and layers of a doped sacrificial material that may be used for forming stacked nanoribbon transistors, according to some embodiments of the present disclosure.

FIG. 10B is a cross-section through a die that includes an active area with a set of stacked transistors formed from the layered materials of FIG. 10A and regions outside of the active area, according to some embodiments of the present disclosure.

FIG. 11A is a cross-section of alternating layers of a semiconductor channel material, layers of a doped channel material, and layers of a doped sacrificial material that may be used for forming stacked nanoribbon transistors, according to some embodiments of the present disclosure.

FIG. 11B is a cross-section through a die that includes an active area with a set of stacked transistors formed from the layered materials of FIG. 11A and regions outside of the active area, according to some embodiments of the present disclosure.

FIG. 12A is a cross-section of alternating layers of a semiconductor channel material and a doped sacrificial material that may be used for forming stacked nanoribbon transistors, according to some embodiments of the present disclosure.

FIG. 12B is a cross-section through a die that includes an active area with a set of stacked transistors formed from the layered materials of FIG. 12A and regions outside of the active area, according to some embodiments of the present disclosure.

FIG. 13A is a cross-section of alternating layers of a semiconductor channel material, layers of a sacrificial material, and layers of a doped sacrificial material that may be used for forming stacked nanoribbon transistors, according to some embodiments of the present disclosure.

FIG. 13B is a cross-section through a die that includes an active area with a set of stacked transistors formed from the layered materials of FIG. 13A and regions outside of the active area, according to some embodiments of the present disclosure.

FIG. 14A is a top view of a wafer and FIG. 14B a top view of dies that may include one or more nanoribbon transistors formed from stacked materials with a strain dopant in accordance with any of the embodiments disclosed herein.

FIG. 15 is a cross-sectional side view of an IC device that may include one or more rows of nanoribbon transistors formed from stacked materials with a strain dopant in accordance with any of the embodiments disclosed herein.

FIG. 16 is a cross-sectional side view of an IC device assembly that may include one or more nanoribbon transistors formed from stacked materials with a strain dopant in accordance with any of the embodiments disclosed herein.

FIG. 17 is a block diagram of an example computing device that may include one or more nanoribbon transistors formed from stacked materials with a strain dopant in accordance with any of the embodiments disclosed herein.

### DETAILED DESCRIPTION

### Overview

The systems, methods and devices of this disclosure each have several innovative aspects, no single one of which is solely responsible for all desirable attributes disclosed herein. Details of one or more implementations of the subject matter described in this specification are set forth in the description below and the accompanying drawings.

For purposes of illustrating nanoribbon transistors formed from stacked materials with a strain dopant as described herein, it might be useful to first understand phenomena that may come into play in certain IC arrangements. The following foundational information may be viewed as a basis from which the present disclosure may be properly explained. Such information is offered for purposes of explanation only and, accordingly, should not be construed in any way to limit the broad scope of the present disclosure and its potential applications.

Certain embodiments described herein relate to non-planar transistors, including nanoribbon transistors. In a nanoribbon transistor, a gate stack that may include one or more gate electrode materials and a gate dielectric may be provided around a portion of an elongated semiconductor structure called “nanoribbon”, forming the gate stack on all sides of the nanoribbon. A source region and a drain region are provided on the opposite ends of the nanoribbon(s) and on either side of the gate stack, forming, respectively, a source and a drain of the nanoribbon transistor. The source and drain regions are insulated from the gate stack, so that the voltages at the three terminals (gate, source, and drain) may be separately controlled.

Non-planar transistors provide several advantages over planar transistor architectures. For example, non-planar transistors provide improved electrostatic transistor control and faster transistor speeds relative to other transistor architectures. For certain applications, nanoribbon-based channels are particularly advantageous, providing increased drive current at smaller scales relative to other non-planar architectures.

Certain embodiments described herein relate to IC devices that include multiple transistor layers, e.g., stacked transistor layers. One example of a stacked transistor device is a complementary field-effect transistor (CFET) device. A CFET is a type of transistor configuration that combines both N-channel and P-channel field-effect transistors (FETs) within the same circuit. This design allows for efficient digital and analog circuitry, especially in complementary metal-oxide-semiconductor (CMOS) technology. In a CFET arrangement, the N-channel FET may operate as an enhancement mode transistor, while the P-channel FET may operate as a depletion mode transistor. When used together, these transistors complement each other's behavior. CFETs may be employed in digital logic gates, memory cells, and various integrated circuits (ICs). The complementary nature of CFETs may reduce power consumption and/or enhance overall circuit performance in modern electronic devices.

When a CFET architecture is used, a layer of NMOS devices may be stacked over a layer of PMOS devices, or vice versa. The CFET transistors may have a non-planar transistor architecture, e.g., the transistors may be FinFETs, GAA transistors, nanoribbon transistors, nanowire transistors, or another transistor architecture. In some cases, individual transistors may be aligned and stacked, e.g., an NMOS transistor in the NMOS layer may be stacked over a PMOS transistor in the PMOS layer. A pair of transistors (e.g., a stacked NMOS and PMOS transistor) may be coupled together in a circuit, e.g., connected in parallel or in series with each other.

As noted above, to form GAA transistors, alternating layers of a channel material and one or more sacrificial materials are deposited. The layers are etched to form stacks of the channel material and sacrificial material. The sacrificial material is selectively removed from the stack and replaced with other material, e.g., a gate dielectric and a gate electrode. The channel material and sacrificial materials include different materials that exhibit etch selectivity, so that the sacrificial material can be removed while leaving the channel material intact. The different materials may also have a lattice mismatch or different strain properties. For example, when alternating layers of silicon (Si) and silicon germanium (SiGe) are deposited over a silicon substrate, the Si layers are stress-neutral, while the SiGe layers are naturally strained. After the layers of material are etched to form stacks, the SiGe layers tend to relax, which can lead to loss of stress within the channel material of the stack. For example, particularly in upper layers of the stack, the SiGe tends to pull to the sides (e.g., outward from the sides of the stack), causing both the SiGe and Si layers to widen. This can lead to reduced electrical performance in the transistors formed from the stack.

As described herein, a dopant may be added to one or more layers of the nanoribbon template to counteract the strain effect of SiGe. In general, the dopant may be added to a layer that is not selected as the channel material. For example, when forming transistors with Si channels, a dopant may be added to one or more sacrificial layers of SiGe, which are removed prior to gate deposition. The dopant may cause the SiGe layers to be more stress neutral, to prevent relaxation after etching the stacks. Alternatively, when forming transistors with SiGe channels, the dopant may be added to one or more sacrificial layers of Si, which are removed prior to gate deposition. The doped Si layers may counteract the elastic stress from the SiGe layers, thus encouraging the SiGe layers to hold their shape after etching the stacks.

The dopant layers may be included at various positions in the material layer. For example, a dopant layer may be used as a capping layer over alternating channel and sacrificial layers. In a stacked transistor embodiment (e.g., a CFET embodiment), dopant layers may be included between channel layers of a given transistor, as a capping layer over the stack, and/or in one or more isolation layers between channel materials for forming different transistors in the stack (e.g., between the channel layers for NMOS and PMOS transistors in a CFET embodiment).

The dopant layer may include one or more dopants selected from carbon, arsenic, boron, and phosphorus. In some embodiments, different dopants may be used in different dopant layers. In some embodiments, multiple different dopants may be included in a single dopant layer.

As noted above, the dopant layer or dopant layers are sacrificial layers that are removed during transistor fabrication. The channel layers and sacrificial layers, including the dopant layers, may be deposited across an area (e.g., across a wafer or die), and portions of the area are used to form semiconductor devices, while other portions (e.g., edges of a die) are inactive areas. The full stack of channel layers and sacrificial layers may remain in a particular IC device (e.g., a die or wafer) after the transistor fabrication process.

The devices described herein may be used in various applications. For example, for a dynamic random-access memory (DRAM) application, a transistor can be coupled to a capacitor. For a static random-access memory (SRAM) application, multiple transistors may be coupled together to form a single memory cell. The transistors described herein may also be used as computing or logic devices.

For purposes of explanation, specific numbers, materials and configurations are set forth in order to provide a thorough understanding of the illustrative implementations. However, it will be apparent to one skilled in the art that the present disclosure may be practiced without the specific details or/and that the present disclosure may be practiced with only some of the described aspects. In other instances, well known features are omitted or simplified in order not to obscure the illustrative implementations.

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. The meaning of “a,” “an,” and “the” include plural references. The meaning of “in” includes “in” and “on.”

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. The terms “substantially,” “close,” “approximately,” “near,” and “about,” generally refer to being within +/−20% of a target value, unless specified otherwise. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

In the following detailed description, various aspects of the illustrative implementations will be described using terms commonly employed by those skilled in the art to convey the substance of their work to others skilled in the art. For example, as used herein, a “READ” and “WRITE” memory access or operations refer to, respectively, determining/sensing a logic state of a memory cell and programming/setting a logic state of a memory cell. In other examples, the term “connected” means a direct electrical or magnetic connection between the things that are connected, without any intermediary devices, while the term “coupled” means either a direct electrical or magnetic connection between the things that are connected or an indirect connection through one or more passive or active intermediary devices. The term “circuit” means one or more passive and/or active components that are arranged to cooperate with one another to provide a desired function. In yet another example, a “high-k dielectric” refers to a material having a higher dielectric constant (k) than silicon oxide. The terms “oxide,” “carbide,” “nitride,” etc. refer to compounds containing, respectively, oxygen, carbon, nitrogen, etc.

In the following, some descriptions may refer to a particular S/D region or contact being either a source region/contact or a drain region/contact. However, unless specified otherwise, which region/contact of a transistor is considered to be a source region/contact and which region/contact is considered to be a drain region/contact is not important because, as is common in the field of FETS, designations of source and drain are often interchangeable. Therefore, descriptions of some illustrative embodiments of the source and drain regions/contacts provided herein are applicable to embodiments where the designation of source and drain regions/contacts may be reversed.

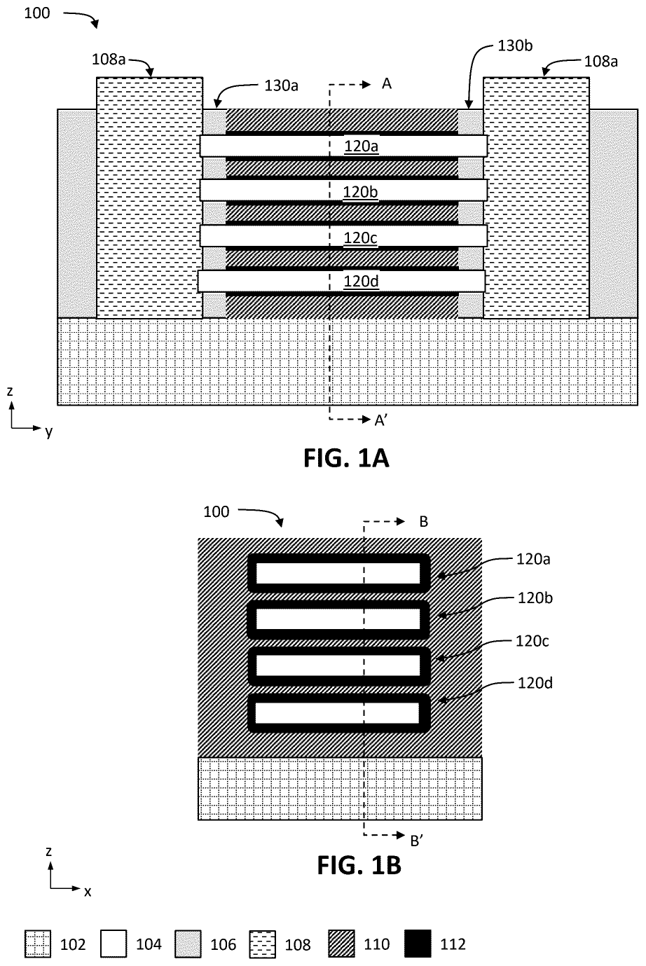

For convenience, if a collection of drawings designated with different letters are present, e.g., FIGS. 1A-1B, such a collection may be referred to herein without the letters, e.g., as “FIG. 1.”

### Example Nanoribbon Transistor

FIGS. 1A and 1B illustrate an example architecture of a nanoribbon-based transistor. FIG. 1A is a cross-section across a transistor 100 showing the source, gate, and drain. FIG. 1B is a cross-section across the gate regions of the transistor 100. FIG. 1B is a cross-section through the plane AA′ in FIG. 1A, and FIG. 1A is a cross-section through the plane BB′ in FIG. 1B. The nanoribbon-based transistor 100 illustrates certain structures and materials that may be used in arrangements of nanoribbon transistors with different widths, discussed further below.

A number of elements referred to in the description of FIGS. 1-13, and with reference numerals are illustrated in these figures with different patterns, with a legend at the bottom of the page showing the correspondence between the reference numerals and patterns. The legend illustrates that FIGS. 1A and 1B use different patterns to show a support structure 102, a channel material 104, a dielectric material 106, a source or drain (S/D) region 108, a gate electrode 110, and a gate dielectric 112.

In the drawings, some example structures of various devices and assemblies described herein are shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication.

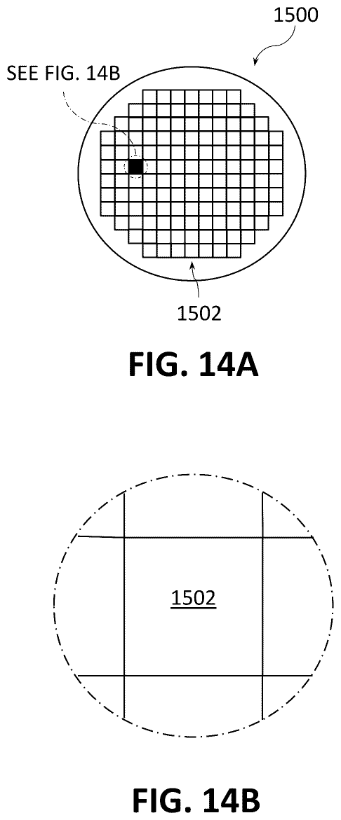

In general, implementations of the present disclosure may be formed or carried out on a support structure, e.g., the support structure 102 illustrated in FIG. 1. The support structure 102 may be, e.g., a substrate, a die, a wafer or a chip. For example, the support structure may be the wafer 1500 of FIG. 14A, discussed below, and may be, or be included in, a die, e.g., the singulated die 1502 of FIG. 14B, discussed below. The support structure 102 extends along the x-y plane in the coordinate system shown in FIG. 1. In some embodiments, a support structure 102 may be used during a fabrication process and later removed. For example, a top side of the transistor 100 may be attached to a second support structure (e.g., a second one of the support structures 102, which may be referred to as a carrier structure), and the support structure 102 over which the transistor 100 is formed may be removed to expose the back side of the transistor 100.

In some embodiments, a support structure may be a substrate that includes silicon and/or hafnium. More generally, the support structure may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline. In some embodiments, the support structure may be a printed circuit board (PCB) substrate. Although a few examples of materials from which the substrate may be formed are described here, any material that may serve as a foundation upon which a semiconductor device including one or more nanoribbon transistors, as described herein, may be built falls within the spirit and scope of the present disclosure.

In FIGS. 1A and 1B, a transistor 100 is formed over a support structure 102. The transistor 100 includes a channel material 104 formed into four nanoribbons stacked on top of each other. In other examples, the transistor 100 may include more or fewer nanoribbons, e.g., one, two, three, five, six or more nanoribbons. The channel material 104 may be a semiconductor, such as silicon or other semiconductor materials described herein.

The transistor 100 includes nanoribbons 120a, 120b, 120c, and 120d, referred to collectively as nanoribbons 120 or individually as a nanoribbon 120. Each nanoribbon 120 is at a different height in the z-direction in the orientation shown in FIGS. 1A and 1B, i.e., a different distance from the support structure 102, where the nanoribbon 120a is the greatest distance from the support structure 102, and the nanoribbon 120d is the smallest distance from the support structure 102. S/D regions 108a and 108b are formed at either end of the nanoribbon channels 120, as illustrated in FIG. 1A.

The nanoribbons 120 may be any three-dimensional semiconductor structures around which the memory cells described herein may be formed, including, for example, nanowires with a square or circular cross-section, or nanosheets with a wider rectangular cross section. The term nanosheet is sometimes used to highlight the relative breadth and thinness of a particular nanoribbon structure. For example, the term nanosheet may indicate that a structure has a small height (in the z-direction in the example coordinate system) and a broader width (into the page in FIG. 1A, i.e., in the x-direction in the coordinate system shown) compared to other nanostructures, like nanowires. In other embodiments, the nanoribbons 120 may have cross-sections that are squares with rounded corners, rectangles with rounded corners, ovals, or other shapes. In some embodiments, the nanoribbons 120 are coupled on one side (e.g., on the right side in the orientation shown in FIG. 1B) to a dielectric fin, and another set of nanoribbons extend from the opposite side of the dielectric fin, thus forming a forksheet arrangement.

In general, to form nanoribbon channels such as the nanoribbon channels 120, alternating layers of the channel material 104 and a sacrificial material are deposited over the support structure 102. The sacrificial material is removed from the stack and replaced with other material, e.g., material for forming a gate stack, so the sacrificial material is not shown in FIG. 1. The channel material 104 and sacrificial materials include different materials. In one example, the channel material 104 is silicon, while the sacrificial material includes silicon and germanium. In another example, the channel material 104 is silicon germanium, while the sacrificial material includes silicon. As described further below, the layers of channel material 104 and sacrificial material may include one or more sacrificial layers that include a dopant. The sacrificial material may be chosen to have a similar crystal structure to the channel material 104, so that monocrystalline layers of the channel material 104 (or substantially monocrystalline layers, e.g., with a grain size of at least 5 nanometers, at least 20 nanometers, at least 50 nanometers, or at least 100 nanometers) and monocrystalline layers of the sacrificial material (or substantially monocrystalline layers) may be formed over each other. In different embodiments, the channel material 104 and/or the sacrificial material may be formed of any suitable single-crystal material, such as sapphire, quartz, silicon, a compound of silicon (e.g., silicon oxide), indium phosphide, germanium or a germanium alloy (e.g., silicon germanium), gallium, arsenic (e.g., an arsenide III compound, where arsenic III is in combination with another element such as boron, aluminum, gallium, or indium), or any group III-V material (i.e., materials from groups III and V of the periodic system of elements).

More generally, the channel material 104 may be composed of semiconductor material systems including, for example, N-type or P-type materials systems. The channel material 104 may include a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. The channel material 104 may include one or more of cobalt oxide, copper oxide, ruthenium oxide, nickel oxide, niobium oxide, copper peroxide, indium telluride, molybdenite, molybdenum diselenide, tungsten diselenide, tungsten disulfide, molybdenum disulfide, N- or P-type amorphous or polycrystalline silicon, monocrystalline silicon, germanium, indium arsenide, indium gallium arsenide, indium selenide, indium antimonide, zinc antimonide, antimony selenide, silicon germanium, gallium nitride, aluminum gallium nitride, indium phosphite, black phosphorus, zinc sulfide, indium sulfide, gallium sulfide, each of which may possibly be doped with one or more of gallium, indium, aluminum, fluorine, boron, phosphorus, arsenic, nitrogen, tantalum, tungsten, and magnesium, etc.

In some cases, multiple channel materials may be included within an IC device. For example, an IC device may include both N-type metal-oxide-semiconductor (NMOS) transistors and P-type MOS (PMOS) transistors, e.g., alternating rows of NMOS and PMOS transistors, or stacks of NMOS and PMOS transistors in a CFET embodiment. NMOS and PMOS logic can use different groups of channel material 104, e.g., silicon may be used to form an N-type semiconductor channel, while silicon germanium may be used to form a P-type semiconductor channel. In some cases, a single channel material 104 is used (e.g., silicon), and different portions (e.g., channel material to form different transistors) may include different dopants, e.g., N-type dopants for NMOS transistors and P-type dopants for PMOS transistors.

The S/D regions 108 may be formed from one or more layers of doped semiconductors, metals, metal alloys, or other materials. For example, the S/D regions 108 may include a doped semiconductor, such as silicon or another semiconductor doped with an N-type dopant or a P-type dopant. The S/D regions 108 may include multiple layers with different levels of conductivity, e.g., a doped semiconductor followed by a more highly doped semiconductor, or a semiconductor followed by metal.

A central portion of each of the nanoribbon channels 120 is surrounded by a gate stack, which in this example, includes a gate electrode 110 and gate dielectric 112. Nanoribbon transistors often include a gate dielectric that surrounds the nanoribbon channels 120, and a gate electrode that surrounds the gate dielectric. While not specifically shown, in some cases, the gate dielectric 112 around each nanoribbon channel 120 includes multiple layers, e.g., an oxide layer and a high-k dielectric layer. The oxide layer may be grown directly on the nanoribbon channels 120, and the high-k dielectric may surround the oxide. The oxide may include oxygen in combination with the channel material 104. For example, if the nanoribbon channels are formed from silicon, the gate dielectric 112 may include a layer of silicon oxide. The high-k dielectric may be formed over the oxide. The gate electrode 110 surrounds the gate dielectric 112, e.g., the high-k dielectric (if included). In this example, the gate electrode 110 is above and below the nanoribbon stack, and between adjacent nanoribbons 120.

The gate electrode 110 includes a conductive material, such as a metal. The gate electrode 110 may include at least one P-type work function metal or N-type work function metal, depending on whether the transistor 100 is a PMOS transistor or an NMOS transistor. For a PMOS transistor, metals that may be used for the gate electrode 110 may include, but are not limited to, ruthenium, palladium, platinum, cobalt, nickel, and conductive metal oxides (e.g., ruthenium oxide). For an NMOS transistor, metals that may be used for the gate electrode 110 include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). The gate electrode 110 may include a stack of two or more metal layers, where one or more metal layers are work function metal layers and at least one metal layer is a fill metal layer.

The gate dielectric 112 may include one or more high-k dielectric materials and may include elements such as hafnium, silicon, oxygen, titanium, tantalum, lanthanum, aluminum, zirconium, barium, strontium, yttrium, lead, scandium, niobium, and zinc. Examples of high-k materials that may be used include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. The gate dielectric 112 may have a thickness between about 0.5 nanometers and 3 nanometers, including all values and ranges therein, e.g., between about 1 and 3 nanometers, or between about 1 and 2 nanometers.

Regions of the transistor 100 outside of the nanoribbons 120, gate stack, and S/D regions 108 are filled in with a dielectric material 106. In the region between the gate stack and the S/D regions 108, the dielectric material 106 forms a series of cavity spacers 130a and 130b. Cavity spacers 130, also referred to as “dimple spacers” or “inner spacers,” provide electrical isolation between the S/D regions 108 formed at the ends of the nanoribbons and the gate electrode 110 deposited around the nanoribbons 120.

FIGS. 1A and 1B illustrate a single nanoribbon transistor 100. In IC devices, many similar or identical transistors are arranged within a transistor layer. The dielectric material 106 and/or different dielectric materials may provide isolation between different transistors, or between other conductive materials in or near the transistor layer.

Example Stacks with Relaxation

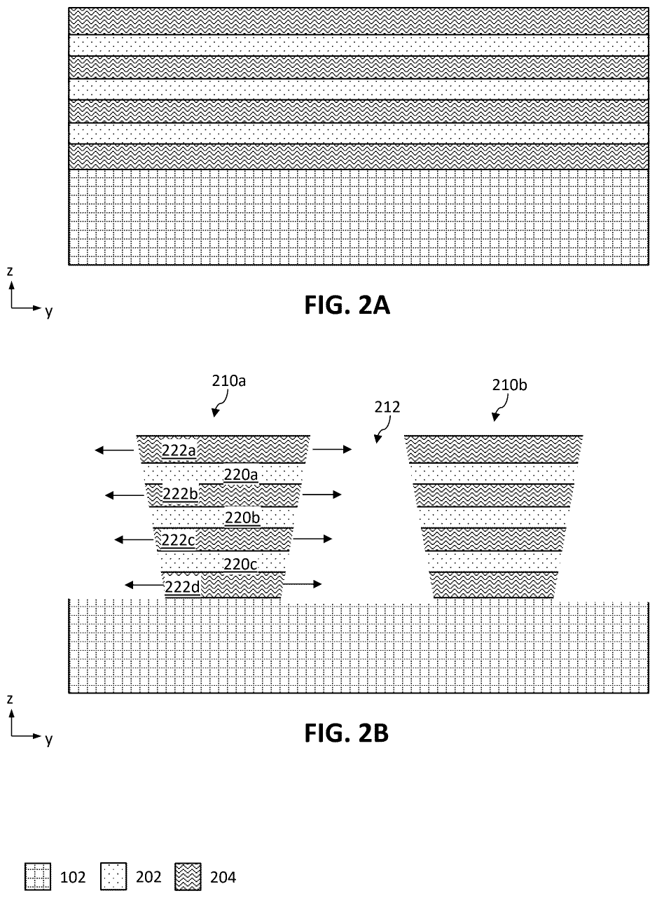

FIG. 2A is a cross-section of alternating layers of a semiconductor channel material and a sacrificial material that may be used for forming nanoribbon transistors. FIG. 2A includes a first material 202 and a second material 204. The first material 202 may be silicon, and specifically, monocrystalline silicon. The second material 204 may include germanium. In some embodiments, the second material 204 also includes silicon. The second material 204 is also monocrystalline. The first and second materials 202 and 204 are not doped, e.g., with carbon, arsenic, boron, or phosphorus. However, the first material 202 and/or second material 204 may include one or more impurities, as a result of the fabrication process, diffusion, or other factors. In the following, the first material 202, as described above, is generally referred to as Si 202, and the second material 204, as described above, is generally referred to as SiGe 204. In some embodiments, the SiGe 204 may include a minimal amount of silicon or may not include silicon.

In FIG. 2A, alternating layers of SiGe 204 and Si 202 are formed over a support structure 102, which may be a silicon substrate or another support structure as described above. In this example, the layers of Si 202 may be used to form nanoribbon channels, while the layers of SiGe 204 are sacrificial layers that are removed during fabrication.

FIG. 2B illustrates the layers of FIG. 2A after stacks have been etched to form individuated channels for different transistors, and showing relaxing of the materials. FIG. 2B may be the result of a process to etch the layers of channel material (e.g., the Si 202) and sacrificial material (e.g., the SiGe 204) to form individuated stacks of nanoribbons, still layered with the sacrificial material. As shown in FIG. 2B, portions of the alternating layers are removed, leaving the stacks 210a and 210b. The stacks 210 include layers 220 of Si 202 and layers 222 of SiGe 204, where each layer 220 is between a pair of the layers 222, e.g., layer 220a is between layers 222a and 222b, etc. The etching may be performed using a lithographic process, e.g., a mask may have been formed over the stacks 210a and 210b so that the material under the masked regions is not removed. The mask may act as a dummy gate until gate fabrication. The stacks 210a and 210b are separated by an etched region 212.

While the etching process may generally remove regions with a rectangular cross-section of the layered materials (e.g., the etched region 212 may initially have a rectangular cross-section in the y-z plane illustrated in FIG. 2B), when portions of the layers of SiGe 204 are removed by etching, the etched layers 222a-222d of SiGe 204 relax into the etched regions, e.g., into the etched region 212, as indicated by the arrows on either side of the layers 222. As illustrated, the amount of relaxation may be greater moving farther away from the support structure 102, e.g., the layers 222a and 220a extend further in the y-direction than the layers 220c and 222d. According to various embodiments disclosed herein, including one or more doped sacrificial layers can prevent or reduce the relaxation illustrated in FIG. 2B.

Example Stacks with Doped Top Layer

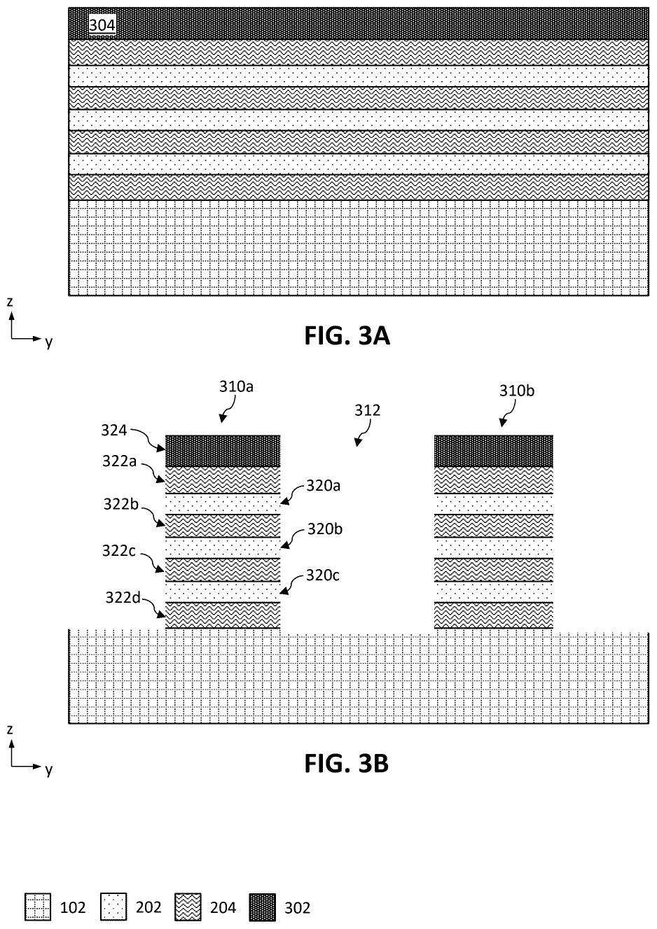

FIG. 3A is a cross-section of alternating layers of a semiconductor channel material and a sacrificial material with a doped top layer that may be used for forming nanoribbon transistors, according to some embodiments of the present disclosure. FIG. 3A illustrates alternating layers of SiGe 204 and Si 202 over a support structure 102. The support structure 102 may be a silicon substrate or another support structure as described above. In this example, the layers of Si 202 may be used to form nanoribbon channels, while the layers of SiGe 204 are sacrificial layers that are removed during fabrication. A layer 304 of a doped material 302 is formed over the alternating layers of Si 202 and SiGe 204. The doped material 302 includes at least one of silicon and germanium and at least one dopant. The dopant may be selected from carbon, arsenic, boron, and phosphorus. In some embodiments, two or more dopants are included, e.g., carbon and arsenic. In some embodiments, the dopant has a concentration between 0.1% and 10% of the doped material 302 by weight. For example, the dopant may have a concentration by weight of the doped material 302 between 0.1% and 1%, between 0.5% and 5%, between 1% and 10%, or within some other range. While the layer 304 of the doped material 302 is illustrated as being over a layer of SiGe 204, in other embodiments, the uppermost layer of SiGe 204 may be removed, and the layer 304 of doped material 302 is directly over the uppermost layer of Si 202. The doped material 302 may have etch selectivity with respect to Si 202 and/or SiGe 204, such that different etch chemistries may be used to selectively remove each of the materials Si 202, SiGe 204, and the doped material 302.

FIG. 3B illustrates the layers of FIG. 3A after stacks have been etched to form individuated channels for different transistors, according to some embodiments of the present disclosure. FIG. 3B may be the result of a process to etch the layers of channel material (e.g., the Si 202), sacrificial material (e.g., the SiGe 204), and top layer 304 to form individuated stacks of nanoribbons layered with the sacrificial material. As shown in FIG. 3B, portions of the alternating layers are removed, leaving the stacks 310a and 310b. The stacks 310 include layers 320 of Si 202 and layers 322 of SiGe 204, where each layer 320 is between a pair of the layers 322, e.g., layer 320a is between layers 322a and 322b, etc.

A top layer 324, also referred to as a cap layer 324, of the doped material 302 is over the layer 322a of SiGe 204 (and over the layers 320 of Si 202). The etching may be performed using a lithographic process, e.g., a mask may have been formed over the stacks 310a and 310b so that the material under the masked regions is not removed. The mask may act as a dummy gate until gate fabrication. The stacks 310a and 310b are separated by an etched region 312.

In this example, the cap layer 324 of the doped material 302 resists relaxation of the etched layers 322a-322d of SiGe 204. The layers 322 and 320 retain their etched shape, and do not widen into the etched regions (e.g., the etch region 312), as they did in FIG. 2B. This maintains the desired geometry and desired electrical properties of the Si 202.

Example Devices with Doped Top Layer

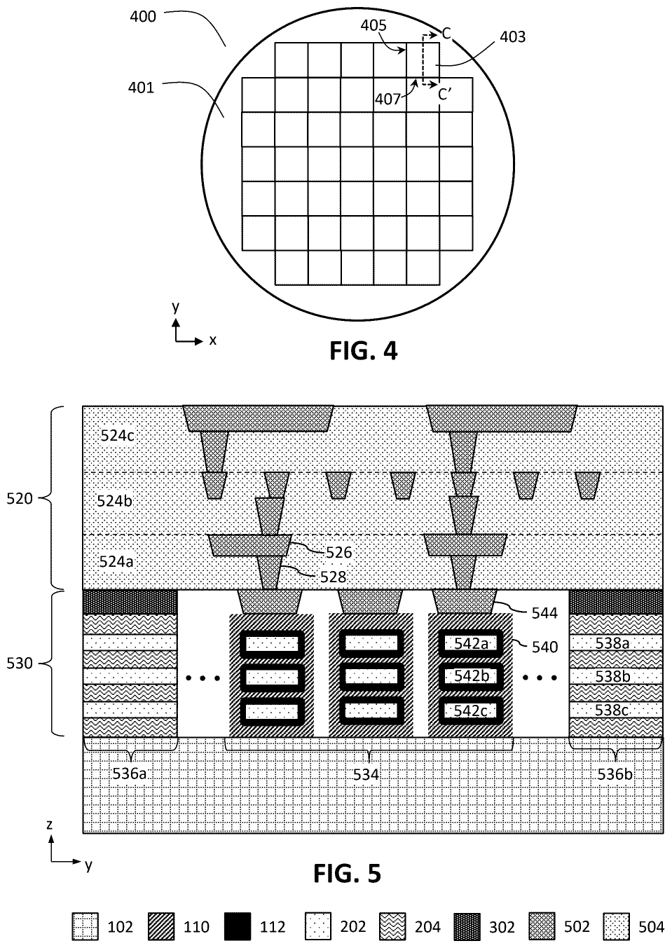

FIG. 4 is a top-down view of a wafer with multiple dies formed thereon, according to some embodiments of the present disclosure. FIG. 4 depicts a wafer 400 with a plurality of dies, e.g., die 403, formed over a support structure 401 and arranged in a grid-like manner across the wafer 400. The wafer 400 may be composed of semiconductor material and include multiple dies having IC structures, such as transistors, formed on a surface of the wafer 400. Each of the dies of the wafer 400 may be a repeating unit of a semiconductor product that includes any suitable IC. The dies may include semiconductor devices for implementing computing logic, e.g., transistors and/or capacitors. Individual dies (e.g., the die 403) may further include circuitry for connecting these devices, e.g., interconnect circuitry that may include lines (or trenches) and vias. The example die 403 has a rectangular shape with four sides, including the sides 405 and 407. The side 405 extends in the x-direction, and the side 407 extends in the y-direction. In some embodiments, the sides 405 and 407 may be the same length, such that the die 403 is square. Adjacent dies may be separated from each other by small spaces (e.g., less than 500 microns, or less than 200 microns) forming a grid, visible in FIG. 4. These spaces are referred to as scribe lines, and typically do not include active circuitry.

FIG. 5 is a cross-section through the plane CC′ of FIG. 4, which is a cross-section through the die 403. FIG. 5 includes gate cross-sections through a set of transistors that may be formed from the stacks 310 of FIG. 3B. FIG. 5 includes a device layer 530 that has an active region 534 in the center of the device layer 530, and, along the edges, two inactive regions 536a and 536b. The inactive regions 536a and 536b may correspond to the regions of the scribe lines of FIG. 4, i.e., regions near the edges of the die 403. The inactive regions 536 may not include circuitry, e.g., the inactive regions 536 may not include transistors or other semiconductor devices.

Each of the inactive regions 536 includes the layered materials of FIG. 3A, i.e., alternating layers of Si 202 and SiGe 204, with a layer of doped material 302 over the uppermost layer of SiGe 204. In the active region 534, the layers of SiGe 204 have been removed and replaced with a gate stack, similar to the gate stack illustrated in FIG. 1B. The layers of Si 202 form nanoribbon channels, e.g., the nanoribbons 542a, 542b, and 542c, which are similar to the nanoribbons 120 described with respect to FIG. 1. The Si 202 and gate stacks (including the gate electrode 110 and gate dielectric 112 described above) form transistors, e.g., the transistor 540 that includes the nanoribbons 542. The doped material 302 has also been removed in the active region 534; in this example, gate contacts, such as the gate contact 544, are aligned with the doped material 302 in the inactive regions 536.

As illustrated, the Si 202 channels in the active region 534 are aligned with the layers of Si 202 in the inactive regions 536. For example, the layer 538c of Si 202 in the inactive region 536b is a same distance away from the support structure 102 as the nanoribbon 542c of the transistor 540. The Si layer 538b is aligned with the nanoribbon 542b, and the Si layer 538a is aligned with the nanoribbon 542a. The cap layer of doped material 302 in each of the inactive regions 536 is a greater distance from the support structure 102 than nanoribbons (e.g., the nanoribbons 542) and the other layers of Si 202 and SiGe 204 in the inactive regions 536.

FIG. 5 includes a front side metallization stack 520 over the device layer 530. In this example, the front side metallization stack 520 includes three front side metal layers 524a, 524b, and 524c, also referred to as interconnect layers. The metal layer 524a is the nearest metal layer to the device layer 530, and the metal layer 524c is the farthest metal layer from the device layer 530. While three metal layers 524a, 524b, and 524c are illustrated in FIG. 5, an IC device may have fewer or more front side metal layers, e.g., up to 10 metal layers, up to 15 metal layers, or more.

Each metal layer 524 includes conductive structures, including metal lines or trenches (e.g., the line 526) formed from a conductive material 502 and vias (e.g., the via 528) formed from the conductive material 502. The conductive material 502 may include one or more metals or metal alloys, with materials such as copper, ruthenium, palladium, platinum, cobalt, nickel, hafnium, zirconium, titanium, tantalum, and aluminum, tantalum nitride, tungsten, doped silicon, doped germanium, or alloys and mixtures of any of these. In some embodiments, the conductive material 502 may include one or more electrically conductive alloys, oxides, or carbides of one or more metals. While FIG. 5 illustrates the same conductive material 502 for the vias and the metal lines, at each metal layer, and for each type of interconnect, any suitable conductive material may be used. For example, in a given layer, the same conductive material may be used for both metal lines and vias, or different materials may be used for metal lines and vias. As another example, in different layers, different materials may be used for the metal lines and/or vias, e.g., ruthenium may be included in the metal lines in the metal layer 524a, while copper is included in the metal lines in the metal layer 524c. In various embodiments, conductive structures may include multiple conductive materials, e.g., a first metal as a liner, and a second metal as a fill.

The conductive material 502 may form conductive pathways to route power, ground, and/or signals to/from various components of the device layer 530. The arrangement of the conductive material 502 in the front side metallization stack 520 in FIG. 5 is merely illustrative, and the conductive pathways in the front side metallization stack 520 may be connected to one another in any suitable manner.

The metal lines and vias in the in the front side metallization stack 520 are surrounded by a dielectric material 504. The dielectric material 504 may be a low-k dielectric. In some embodiments, different dielectric materials may be included in different ones of the metal layers, e.g., the metal layer 524a may include a different dielectric material from the metal layer 524c. In some embodiments, multiple dielectric materials may be present in a given layer. In some embodiments, an etch stop layer, not specifically illustrated, may be present between adjacent layers.

Example Stacks and Devices with Doped Sacrificial Layer

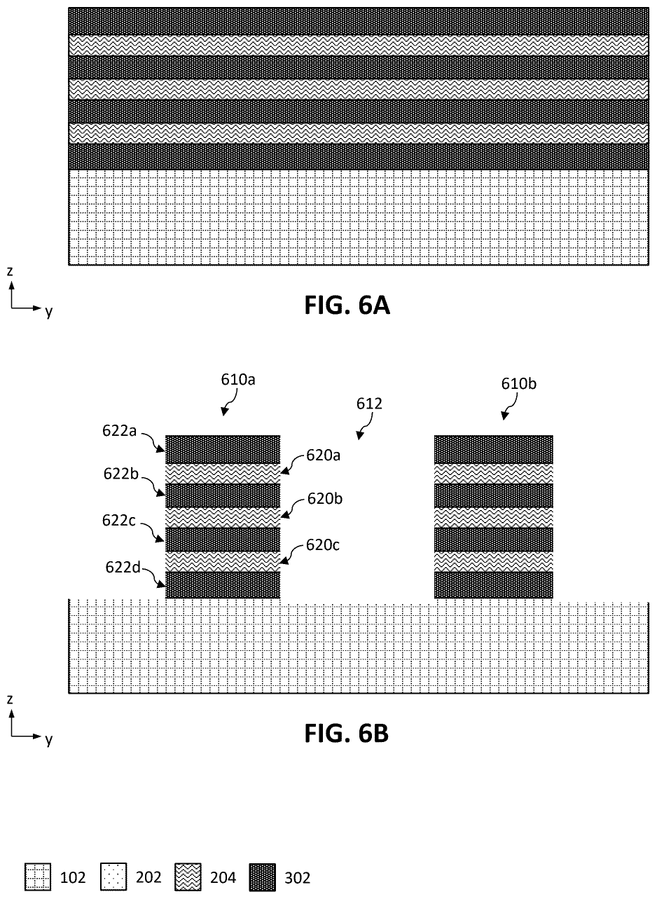

FIG. 6A is a cross-section of alternating layers of a semiconductor channel material and a doped sacrificial material that may be used for forming nanoribbon transistors, according to some embodiments of the present disclosure. FIG. 6A illustrates alternating layers of SiGe 204 and the doped material 302 over a support structure 102. The support structure 102 may be a silicon substrate or another support structure as described above. In this example, the layers of SiGe 204 may be used to form nanoribbon channels, while the layers of the doped material 302 are sacrificial layers that are removed during fabrication. In this particular example, the doped material 302 includes silicon and at least one dopant. The dopant may be selected from carbon, arsenic, boron, and phosphorus. In some embodiments, two or more dopants are included. As described with respect to FIG. 3, the dopant may have a concentration between 0.1% and 10% of the doped material 302 by weight. For example, the dopant may have a concentration by weight of the doped material 302 between 0.1% and 1%, between 0.5% and 5%, between 1% and 10%, or within some other range. The doped material 302 may have etch selectivity with respect to SiGe 204, such that a particular etch chemistries may selectively remove the doped material 302 while leaving the SiGe 204 largely intact. While FIG. 6 illustrates a single doped material 302 across the layers, in some embodiments, different layer of the doped material 302 may include different dopants (e.g., one layer includes carbon, and another layer includes phosphorus) and/or different dopant concentrations (e.g., one layer has 1% of the dopant by weight, and another layer has 2% of the dopant by weight).

FIG. 6B illustrates the layers of FIG. 6A after stacks have been etched to form individuated channels for different transistors, according to some embodiments of the present disclosure. FIG. 6B may be the result of a process to etch the layers of channel material (e.g., the SiGe 204) and sacrificial doped material 302 to form individuated stacks of nanoribbons layered with the sacrificial material. As shown in FIG. 6B, portions of the alternating layers are removed, leaving the stacks 610a and 610b. The stacks 610 include layers 620 of SiGe 204 and layers 622 of the doped material 302, where each layer 620 is between a pair of the layers 622, e.g., layer 620a is between layers 622a and 622b, etc. The etching may be performed using a lithographic process, e.g., a mask may have been formed over the stacks 610a and 610b so that the material under the masked regions is not removed. The mask may act as a dummy gate until gate fabrication. The stacks 610a and 610b are separated by an etched region 612.

In this example, the doped material 302 of the layers 622a-622d resists, or counteracts, relaxation of the etched layers 620a-620c of SiGe 204. The layers 622 and 620 retain their etched shape, and do not widen into the etched regions (e.g., the etch region 612), as they did in FIG. 2B. This maintains the desired geometry and desired electrical properties of SiGe 204 for forming nanoribbon channels.

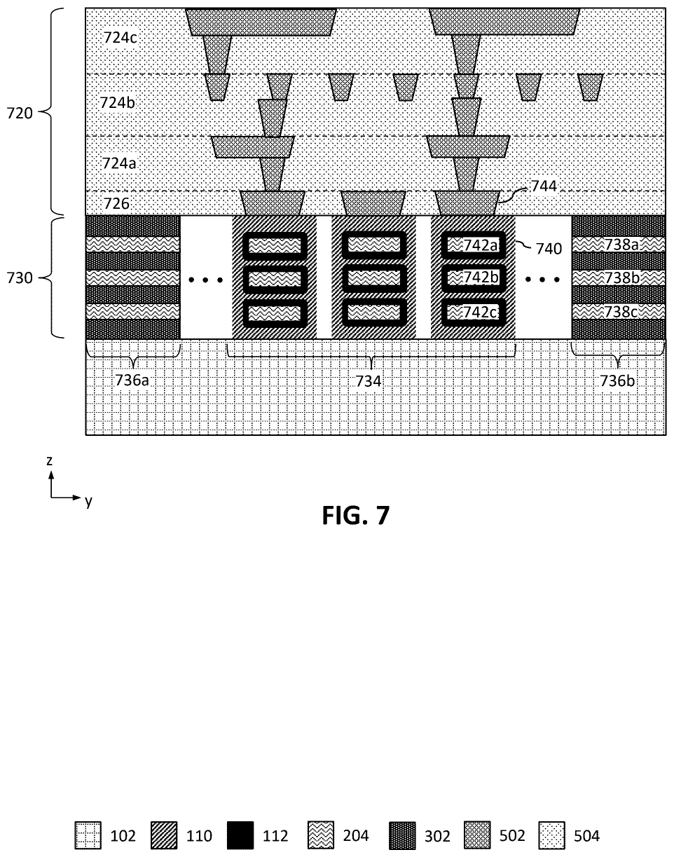

FIG. 7 is a cross-section through a die that includes a set of transistors formed from the stacks of FIG. 6B and regions outside of the active area that include the layered materials of FIG. 6A, according to some embodiments of the present disclosure. FIG. 7 is an alternate embodiment of a cross-section through the plane CC′ of FIG. 4, which is a cross-section through the die 403. FIG. 7 includes gate cross-sections through a set of transistors that may be formed from the stacks 610 of FIG. 6B. FIG. 7 includes a device layer 730 that has an active region 734 in the center of the device layer 730, and, along the edges, two inactive regions 736a and 736b. The inactive regions 736a and 736b may correspond to the regions of the scribe lines of FIG. 4, i.e., regions near the edges of the die 403.

Each of the inactive regions 736 includes the layered materials of FIG. 6A, i.e., alternating layers of SiGe 204 and the doped material 302. In the active region 734, the layers of the doped material 302 have been removed and replaced with a gate stack, similar to the gate stack illustrated in FIG. 1B. The layers of SiGe 204 form nanoribbon channels, e.g., the nanoribbons 742a, 742b, and 742c, which are similar to the nanoribbons 120 described with respect to FIG. 1. The SiGe 204 gate stacks (including the gate electrode 110 and gate dielectric 112 described above) form transistors, e.g., the transistor 740 that includes the nanoribbons 742.

As illustrated, the SiGe 204 channels in the active region 734 are aligned with the layers of SiGe 204 in the inactive regions 736. For example, the layer 738c of SiGe 204 in the inactive region 736b is a same distance away from the support structure 102 as the nanoribbon 742c of the transistor 740. The SiGe layer 738b is aligned with the nanoribbon 742b, and the SiGe layer 738a is aligned with the nanoribbon 742a.

FIG. 7 includes a front side metallization stack 720 over the device layer 730. The front side metallization stack 720 is similar to the front side metallization stack 520 and includes three front side metal layers 724a, 724b, and 724c, which are similar to the front side metal layers 524a, 524b, and 524c described above. In this example, gate contacts, such as the gate contact 744, are in a lowest layer 726 of the front side metallization stack 720.

Example CFET Template and Devices with Doped Sacrificial Layer

FIGS. 3-7 provided example layered material, stacks, and devices that included a single transistor layer, e.g., the device layer 530 and the device layer 730. In other embodiments, a stack of materials (e.g., alternating layers of a channel material and one or more sacrificial materials) may be used to fabricate stacked nanoribbon transistors, such as CFETs.

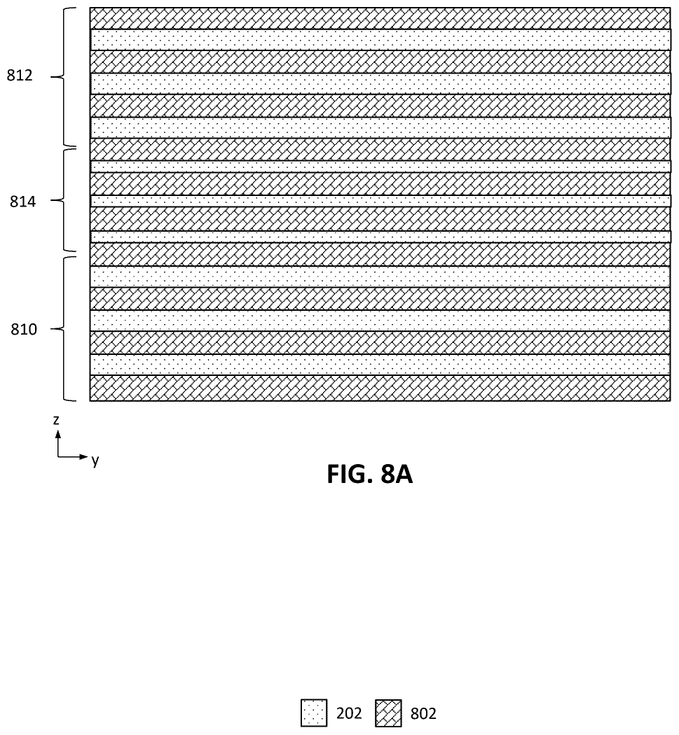

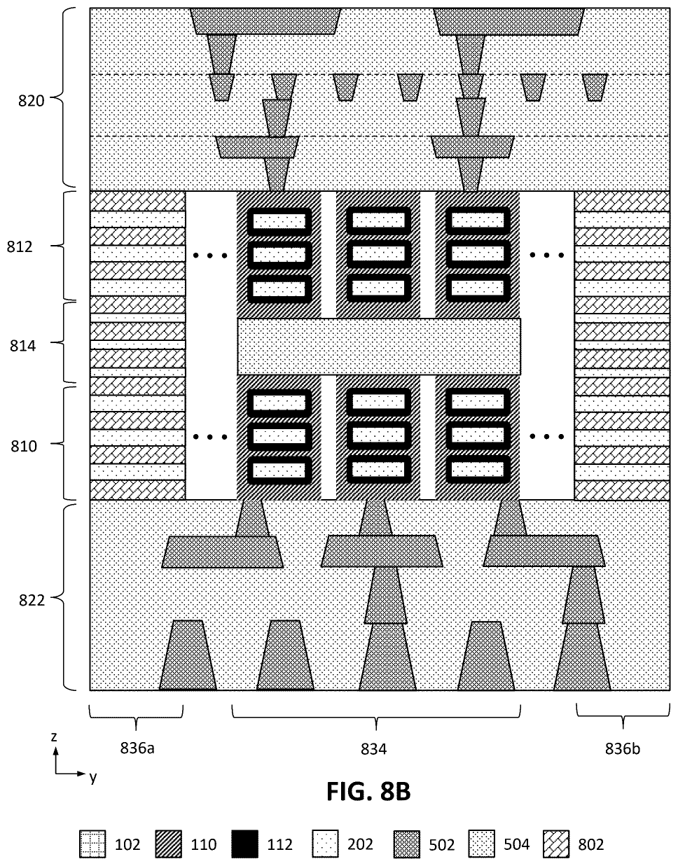

FIG. 8A is a cross-section of alternating layers of a semiconductor channel material and a doped sacrificial material that may be used for forming stacked nanoribbon transistors, according to some embodiments of the present disclosure. FIG. 8A illustrates alternating layers of Si 202 and a doped material 802. While not specifically shown, the layers may be formed over a support structure, e.g., the support structure 102. In this example, the layers of Si 202 may be used to form nanoribbon channels, while the layers of the doped material 802 are sacrificial layers that are removed during fabrication.

The doped material 802 includes germanium and at least one dopant. The doped material 802 may further include silicon, e.g., the doped material 802 is doped silicon germanium. The dopant may be selected from carbon, arsenic, boron, and phosphorus. In some embodiments, two or more dopants are included. The dopant may have a concentration between 0.1% and 10% of the doped material 802 by weight. For example, the dopant may have a concentration by weight of the doped material 802 between 0.1% and 1%, between 0.5% and 5%, between 1% and 10%, or within some other range. The doped material 802 may have etch selectivity with respect to Si 202, such that a particular etch chemistries may selectively remove the doped material 802 while leaving the Si 202 largely intact.

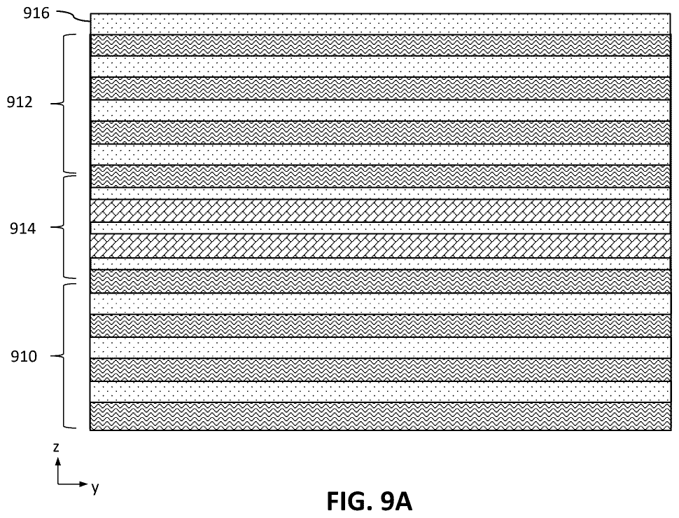

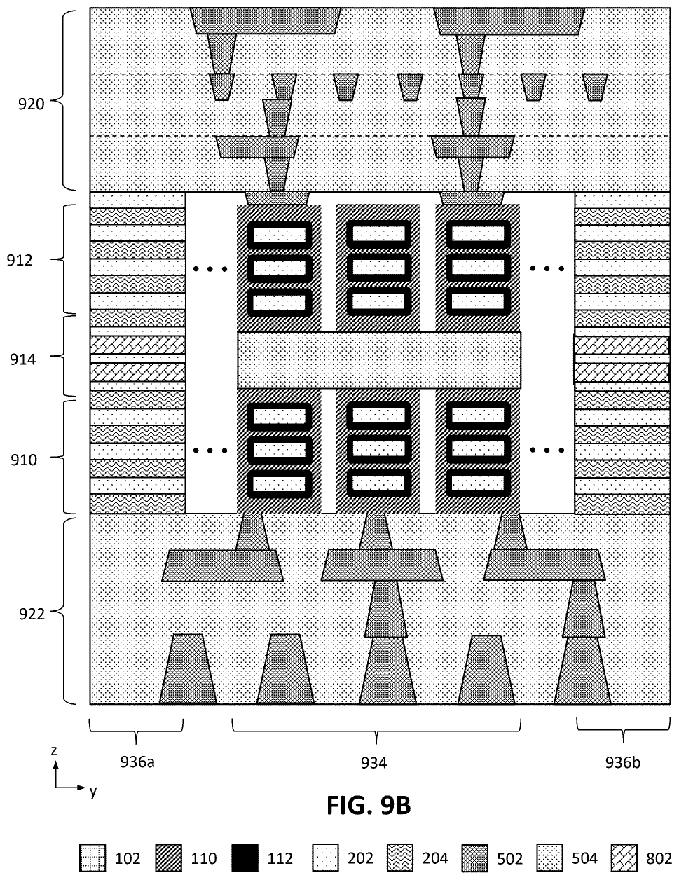

The materials layers in FIG. 8A are arranged in three layers 810, 812, and 814. The layers 810 and 812, which correspond to device layers after transistor fabrication, include templates for nanoribbons in two different stacks. The layer 814 corresponds to an isolation region or isolation layer between the device layers 810 and 812. In the isolation region 814, the layers of Si 202 are thinner than the layers of Si 202 in the device layers 810 and 812. While in this example, and the examples shown in FIGS. 9-13, the same material (here, Si 202) is illustrated as the channel material in both device layers 810 and 812, in other examples, different materials (e.g., Si 202 and SiGe 204, or Si 202 with added dopants associated with different carrier types) are used as the channel materials in the different device layers 810 and 812. Furthermore, in this example and the examples of FIG. 9-13, different layers of a doped material may include different dopants (e.g., one layer includes carbon, and another layer includes phosphorus) and/or different dopant concentrations (e.g., one layer has 1% of the dopant by weight, and another layer has 2% of the dopant by weight). For example, layers of the doped material 802 in different layers 810, 812, and/or 814 may have different compositions.

FIG. 8B is a cross-section through a die that includes an active area with a set of stacked transistors formed from the layered materials of FIG. 8A and regions outside of the active area, according to some embodiments of the present disclosure. FIG. 8B may be an alternate embodiment of a cross-section through the plane CC′ of FIG. 4, which is a cross-section through the die 403. FIG. 8B includes gate cross-sections through a set of transistors that may be formed from the layered materials of FIG. 8A. The layered materials may be etched to form individuated stacks, in a similar manner to that described with respect to FIGS. 2B, 3B, and 6B.

FIG. 8B includes the device layers 810 and 812, as well as the isolation region 814 between the device layers 810 and 812. Within the layers 810-814, there is an active region 834 that includes the centers of the device layers 810 and 812, and, along the edges, two inactive regions 836a and 836b. The inactive regions 836a and 836b may correspond to the regions of the scribe lines of FIG. 4, i.e., regions near the edges of the die 403.

Each of the inactive regions 836 includes the layered materials of FIG. 8A, i.e., alternating layers of Si 202 and the doped material 802. In the device layers 810 and 812, the layers of the doped material 802 have been removed and replaced with gate stacks, similar to the gate stack illustrated in FIG. 1B. The layers of Si 202 in the device layers 810 and 812 form nanoribbon channels that are similar to the nanoribbons 120 described with respect to FIG. 1. The Si 202 and the gate stacks (including the gate electrode 110 and gate dielectric 112 described above) form transistors within the active region 834 of the two device layers 810 and 812. In the active region 834 of the isolation region 814, the Si 202 and doped material 802 have been removed and replaced with a dielectric material 504.

In a similar manner to FIGS. 5 and 7, in this example, in the device layers 810 and 810, the Si 202 channels in the active region 834 are aligned with the layers of Si 202 in the inactive regions 836. In this example, a portion of the layers of the doped material 802 in the inactive regions 836 are aligned with transistors in the device layer 810 (and, in particular, aligned with portions of the gate stack); another portion of the layers of the doped material 802 in the inactive regions 836 are aligned with transistors in the device layer 812 (and, in particular, aligned with portions of the gate stack); and another portion of the layers of the doped material 802 in the inactive region 836 are aligned with the dielectric material 504 in the isolation region 814.

FIG. 8B includes a front side metallization stack 820 over the device layer 812. The front side metallization stack 820 is similar to the front side metallization stacks 520 and 720, described above. FIG. 8B further includes a back side metallization stack 822 below the device layer 810. The back side metallization stack 822 has similar structures and materials to the front side metallization stack 820. The front side metallization stack 820 may provide connections (e.g., for signal and/or power) to transistors in the device layers 812, while the back side metallization stack 822 may provide connections (e.g., for signal and/or power) to transistors in the device layers 810. In some embodiments, although not specifically shown in FIG. 8B, electrical connections may extend between one or more transistors in the device layers 810 and 812, e.g., through the isolation region 814. For example, one or more vias may extend through the isolation region 814 and connect to transistor devices and/or interconnects in the front side metallization stack 820 or back side metallization stack 822 on either side of the isolation region 814.

### Additional Examples of Layers for Stacked Devices

FIGS. 9-13 illustrate additional examples of layered materials (e.g., alternating layers of a channel material and one or more sacrificial materials) may be used to fabricate stacked nanoribbon transistors, such as CFETs, and resulting stacked transistor devices. In each of these examples, one or more layers of a doped semiconductor material is included in the templating layers in order to reduce relaxation of SiGe channels. In various embodiments, different materials (e.g., Si or SiGe) may be used as the channel material, and the doped layers may be included in different positions within the layers. The illustrations provided herein are examples, and different arrangements of layers from those specifically illustrated should be understood as being within the scope of this disclosure.

FIG. 9A is a cross-section of alternating layers of a semiconductor channel material, layers of an undoped sacrificial material, and layers of a doped sacrificial material that may be used for forming stacked nanoribbon transistors, according to some embodiments of the present disclosure.

FIG. 9A illustrates alternating layers of Si 202 and two sacrificial materials: SiGe 204 and the doped material 802. While not specifically shown, the layers may be formed over a support structure, e.g., the support structure 102. In this example, the layers of Si 202 may be used to form nanoribbon channels, while the layers of SiGe 204 and the doped material 802 are sacrificial layers that are removed during fabrication.

FIG. 9A includes three layers 910, 912, and 914. The layers 910 and 912, which correspond to device layers after transistor fabrication, include templates for nanoribbons in two different stacks. The layer 914 corresponds to an isolation region between the layers 910 and 912. In the isolation region 914, the layers of Si 202 are thinner than the layers of Si 202 in the device layers 910 and 912.

In the device layers 910 and 912, SiGe 204 is used as the sacrificial material. The doped material 802 is between layers of Si 202 in the isolation region 914. Including the doped material 802 in the isolation region 914, but not in the device layers 910 and 912, may help prevent or reduce diffusion of the dopant into the channel material, i.e., the layers of Si 202 in the device layers 910 and 912.

FIG. 9B is a cross-section through a die that includes an active area with a set of stacked transistors formed from the layered materials of FIG. 9A and regions outside of the active area, according to some embodiments of the present disclosure. FIG. 9B may be an alternate embodiment of a cross-section through the plane CC′ of FIG. 4, which is a cross-section through the die 403. FIG. 9B includes gate cross-sections through a set of transistors that may be formed from the layered materials of FIG. 9A. The layered materials may be etched to form individuated stacks, in a similar manner to that described with respect to FIGS. 2B, 3B, and 6B.

FIG. 9B includes the device layers 910 and 912, as well as the isolation region 914 between the device layers 910 and 912. Within the layers 910-914, there is an active region 934 that includes the centers of the device layers 910 and 912, and, along the edges, two inactive regions 936a and 936b. The inactive regions 936a and 936b may correspond to the regions of the scribe lines of FIG. 4, i.e., regions near the edges of the die 403.

Each of the inactive regions 936 includes the layered materials of FIG. 9A, i.e., alternating layers of Si 202, SiGe 204, and the doped material 802, in the arrangement shown in FIG. 9A. In the device layers 910 and 912, the layers of SiGe 204 have been removed and replaced with gate stacks, similar to the gate stack illustrated in FIG. 1B. The layers of Si 202 in the device layers 910 and 912 form nanoribbon channels that are similar to the nanoribbons 120 described with respect to FIG. 1. The Si 202 and the gate stacks (including the gate electrode 110 and gate dielectric 112 described above) form transistors within the active region 934 of the two device layers 910 and 912. In the active region 934 of the isolation region 914, the Si 202 and doped material 802 have been removed and replaced with a dielectric material 504.

In a similar manner to FIGS. 5 and 7, in this example, in the device layers 910 and 912, the Si 202 channels in the active region 934 are aligned with the layers of Si 202 in the inactive regions 936. In this example, a portion of the layers of SiGe 204 in the inactive regions 936 are aligned with transistors in the device layer 910 (and, in particular, aligned with portions of the gate stack); another portion of the layers of SiGe 204 in the inactive regions 936 are aligned with transistors in the device layer 912 (and, in particular, aligned with portions of the gate stack). The layers of the doped material 802 in the inactive region 936 are aligned with the dielectric material 504 in the isolation region 914.

FIG. 9B further includes a front side metallization stack 920 over the device layer 912 and a back side metallization stack 922 under the device layer 910. The front side metallization stack 920 and back side metallization stack 922 are similar to the metallization stack 820 and 822 of FIG. 8B.

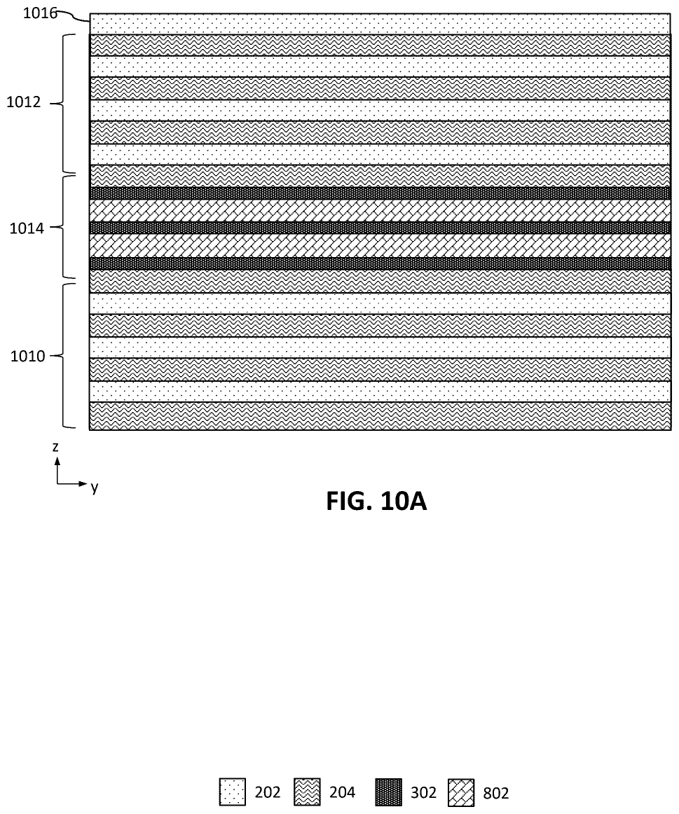

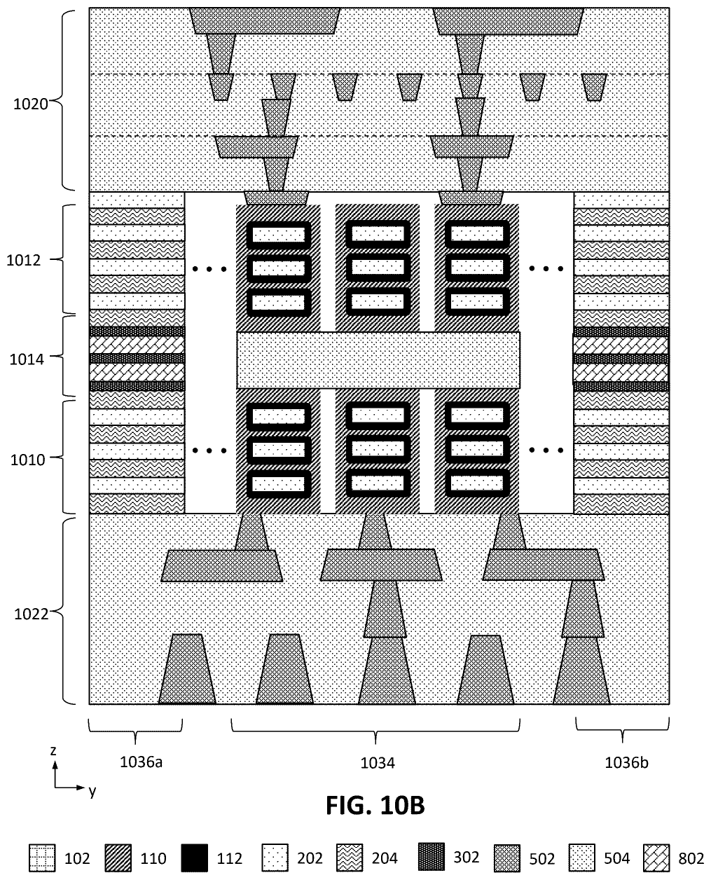

FIG. 10A is a cross-section of alternating layers of a semiconductor channel material, layers of a doped channel material, layers of an undoped sacrificial material, and layers of a doped sacrificial material that may be used for forming stacked nanoribbon transistors, according to some embodiments of the present disclosure.

FIG. 10A illustrates layers of Si 202 and three sacrificial materials: SiGe 204, the doped material 302 (which may be doped silicon, as described above), and the doped material 802 (which may be doped germanium or doped silicon germanium, as described above). While not specifically shown, the layers may be formed over a support structure, e.g., the support structure 102. In this example, the layers of Si 202 may be used to form nanoribbon channels, while layers of the other materials are sacrificial layers that are removed during fabrication.

FIG. 10A includes two device layers 1010 and 1012 and an isolation region 1014 between the device layers 1010 and 1012. In the isolation region 1014, the layers of the doped material 302 are thinner than the layers of Si 202 in the device layers 1010 and 1012. The layers of material further includes a cap layer 1016 of Si 202. In other embodiments, the cap layer 1016 may include a different material, e.g., one of the materials 204, 302, or 802.

In the device layers 1010 and 1012, SiGe 204 is used as the sacrificial material. The doped materials 302 and 802 are in alternating layers in the isolation region 1014. Including the doped materials 302 and 802 in the isolation region 1014, but not in the device layers 1010 and 1012, may help prevent or reduce diffusion of the dopant into the channel material, i.e., the layers of Si 202 in the device layers 1010 and 1012.

FIG. 10B is a cross-section through a die that includes an active area with a set of stacked transistors formed from the layered materials of FIG. 10A and regions outside of the active area, according to some embodiments of the present disclosure. FIG. 10B may be an alternate embodiment of a cross-section through the plane CC′ of FIG. 4, which is a cross-section through the die 403. FIG. 10B includes gate cross-sections through a set of transistors that may be formed from the layered materials of FIG. 10A. The layered materials may be etched to form individuated stacks, in a similar manner to that described with respect to FIGS. 2B, 3B, and 6B.

FIG. 10B includes the device layers 1010 and 1012, as well as the isolation region 1014 between the device layers 1010 and 1012. Within the layers 1010-1014, there is an active region 1034 that includes the centers of the device layers 1010 and 1012, and, along the edges, two inactive regions 1036a and 1036b. The inactive regions 1036a and 1036b may correspond to the regions of the scribe lines of FIG. 4, i.e., regions near the edges of the die 403.

Each of the inactive regions 1036 includes the layered materials of FIG. 10A, i.e., alternating layers of Si 202, SiGe 204, and the doped materials 302 and 802, in the arrangement shown in FIG. 10A. In the device layers 1010 and 1012, the layers of SiGe 204 have been removed and replaced with gate stacks, similar to the gate stack illustrated in FIG. 1B. The layers of Si 202 in the device layers 1010 and 1012 form nanoribbon channels that are similar to the nanoribbons 120 described with respect to FIG. 1. The Si 202 and the gate stacks (including the gate electrode 110 and gate dielectric 112 described above) form transistors within the active region 1034 of the two device layers 1010 and 1012. In the active region 1034 of the isolation region 1014, the doped materials 302 and 802 have been removed and replaced with a dielectric material 504.

In a similar manner to FIGS. 5 and 7, in this example, in the device layers 1010 and 1012, the Si 202 channels in the active region 1034 are aligned with the layers of Si 202 in the inactive regions 1036. In this example, a portion of the layers of SiGe 204 in the inactive regions 1036 are aligned with transistors in the device layer 1010 (and, in particular, aligned with portions of the gate stack); another portion of the layers of SiGe 204 in the inactive regions 1036 are aligned with transistors in the device layer 1012 (and, in particular, aligned with portions of the gate stack). The layers of the doped materials 302 and 802 in the inactive region 1036 are aligned with the dielectric material 504 in the isolation region 1014.

FIG. 10B further includes a front side metallization stack 1020 over the device layer 1012 and a back side metallization stack 1022 under the device layer 1010. The front side metallization stack 1020 and back side metallization stack 1022 are similar to the metallization stack 820 and 822 of FIG. 8B.

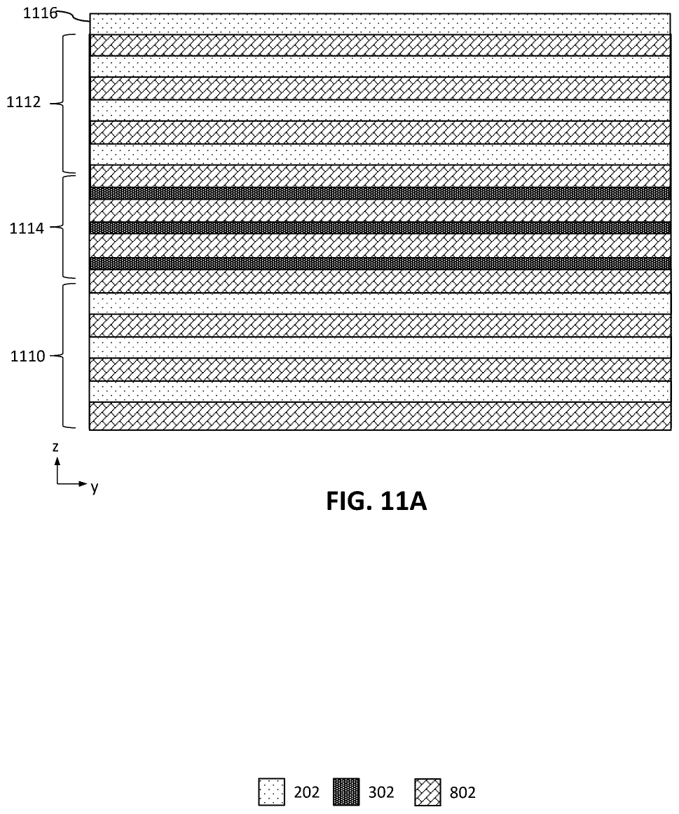

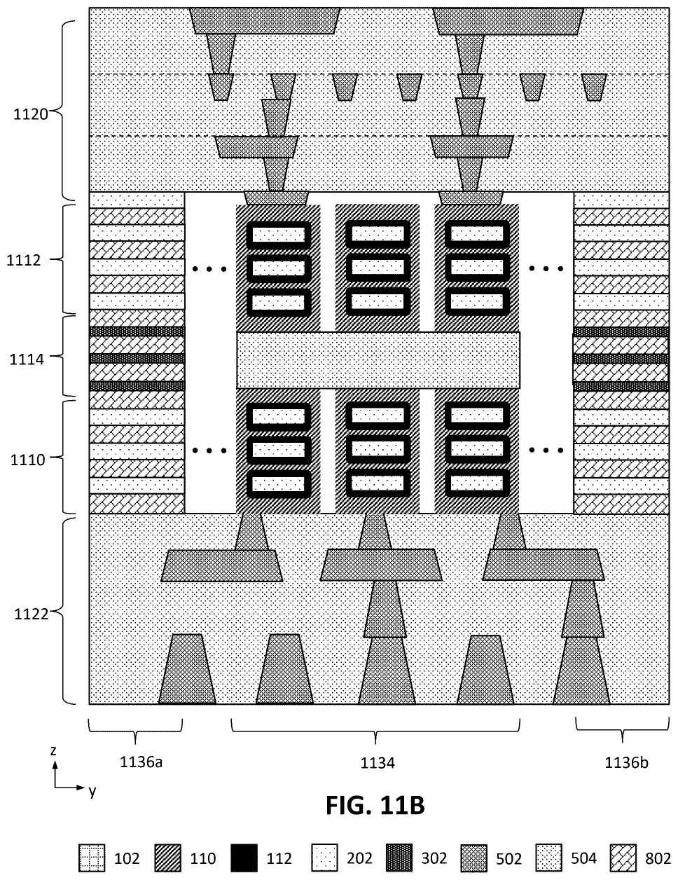

FIG. 11A is a cross-section of alternating layers of a semiconductor channel material, layers of a doped channel material, and layers of a doped sacrificial material that may be used for forming stacked nanoribbon transistors, according to some embodiments of the present disclosure.

FIG. 11A illustrates layers of Si 202 and sacrificial layers of the doped material 302 (which may be doped silicon, as described above), and the doped material 802 (which may be doped germanium or doped silicon germanium, as described above). As in prior examples, the layers may be formed over a support structure, e.g., the support structure 102. The layers of Si 202 may be used to form nanoribbon channels, while layers of the other materials are sacrificial layers that are removed during fabrication.

FIG. 11A includes two device layers 1110 and 1112 and an isolation region 1114 between the device layers 1110 and 1112. In the isolation region 1114, the layers of the doped material 302 are thinner than the layers of Si 202 in the device layers 1110 and 1112. The layers further include a cap layer 1116 of Si 202. In other embodiments, the cap layer 1116 may include a different material, e.g., one of the materials 204, 302, or 802.

In the device layers 1110 and 1112, the doped material 802 is used as the sacrificial material. The doped materials 302 and 802 are in alternating layers in the isolation region 1114. Including the doped materials 302 and 802 in the isolation region 1114, and also as sacrificial layers in the device layers 1110 and 1112, may minimize the strain effects described with respect to FIG. 2.

FIG. 11B is a cross-section through a die that includes an active area with a set of stacked transistors formed from the layered materials of FIG. 11A and regions outside of the active area, according to some embodiments of the present disclosure. FIG. 11B may be another alternate embodiment of a cross-section through the plane CC′ of FIG. 4.

FIG. 11B includes the device layers 1110 and 1112, as well as the isolation region 1114 between the device layers 1110 and 1112. FIG. 11B illustrates an active region 1134 that includes the centers of the device layers 1110 and 1112, and, along the edges, two inactive regions 1136a and 1136b. The inactive regions 1136a and 1136b may correspond to the regions of the scribe lines of FIG. 4, i.e., regions near the edges of the die 403.

Each of the inactive regions 1136 includes the layered materials of FIG. 11A. In the device layers 1110 and 1112, the doped material 802 has been removed and replaced with gate stacks, similar to the gate stack illustrated in FIG. 1B. The layers of Si 202 in the device layers 1110 and 1112 form nanoribbon channels that are similar to the nanoribbons 120 described with respect to FIG. 1. The Si 202 and the gate stacks (including the gate electrode 110 and gate dielectric 112 described above) form transistors within the active region 1134 of the two device layers 1110 and 1112. In the active region 1134 of the isolation region 1114, the doped materials 302 and 802 have been removed and replaced with a dielectric material 504.

In the device layers 1110 and 1112, the Si 202 channels in the active region 1134 are aligned with the layers of Si 202 in the inactive regions 1136. In this example, a portion of the layers of the doped material 802 in the inactive regions 1136 are aligned with transistors in the device layer 1110 (and, in particular, aligned with portions of the gate stack); another portion of the layers of the doped material 802 in the inactive regions 1136 are aligned with transistors in the device layer 1112 (and, in particular, aligned with portions of the gate stack). The layers of the doped materials 302 and 802 in the inactive region 1136 are aligned with the dielectric material 504 in the isolation region 1114.

FIG. 11B further includes a front side metallization stack 1120 over the device layer 1112 and a back side metallization stack 1122 under the device layer 1110. The front side metallization stack 1120 and back side metallization stack 1122 are similar to the metallization stack 820 and 822 of FIG. 8B.

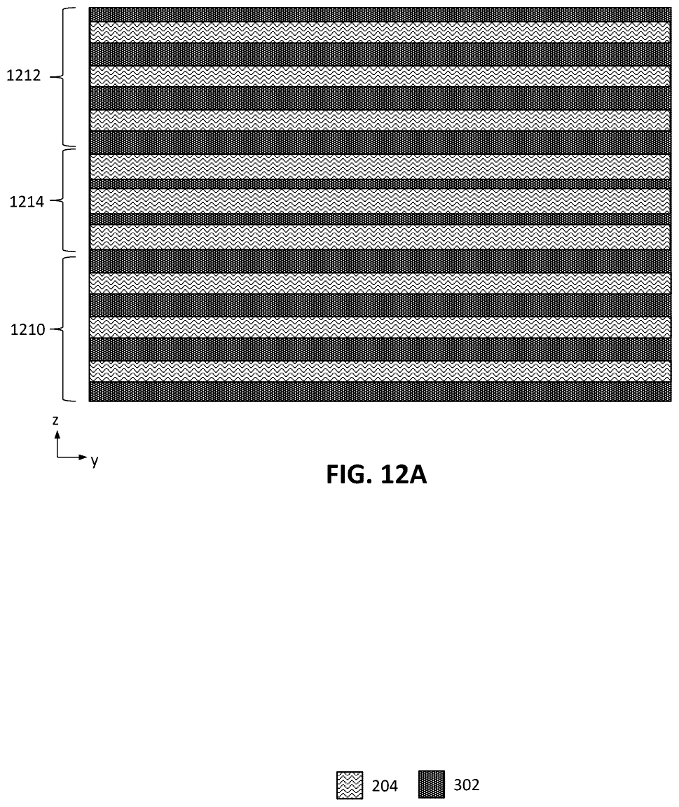

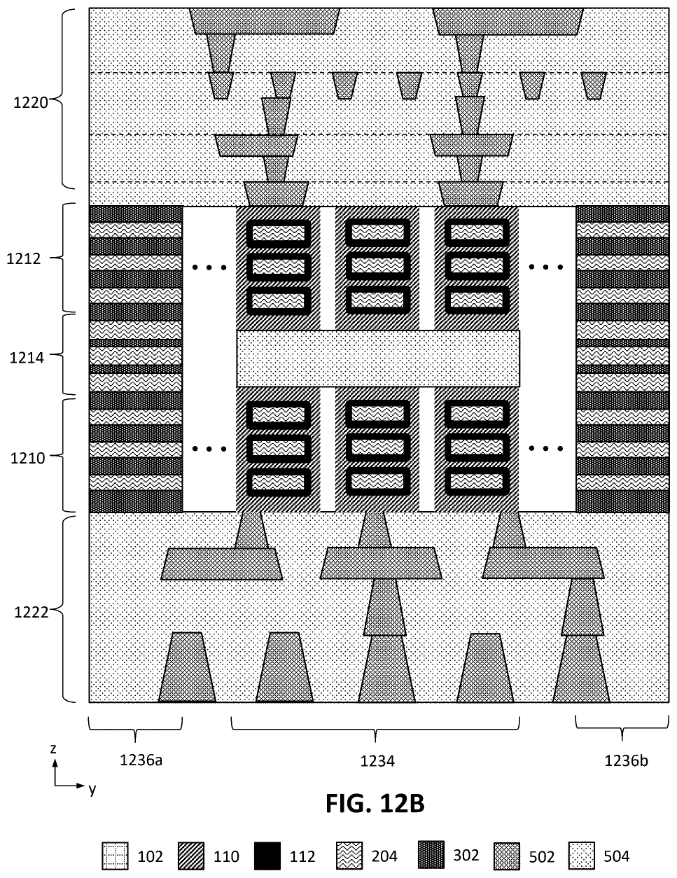

FIG. 12A is a cross-section of alternating layers of a semiconductor channel material and a doped sacrificial material that may be used for forming stacked nanoribbon transistors, according to some embodiments of the present disclosure.

FIG. 12A illustrates layers of SiGe 204 and sacrificial layers of the doped material 302 (which may be doped silicon, as described above). As in prior examples, the layers may be formed over a support structure, e.g., the support structure 102. The layers of SiGe 204 may be used to form nanoribbon channels, while layers of the doped material 302 are sacrificial layers that are removed during fabrication.

FIG. 12A includes two device layers 1210 and 1212 and an isolation region 1214 between the device layers 1210 and 1212. In the isolation region 1214, the layers of the doped material 302 are thinner than the layers of the doped material 302 in the device layers 1210 and 1212, while layers of the SiGe 204 in the isolation region 1214 have the same or similar thickness to layers of SiGe in the device layers 1210 and 1212. In other embodiments, in the isolation region 1214, the layers of SiGe 204 may be relatively thin, e.g., thinner than the layers of SiGe 204 in the device layers 1210 and 1212.

In the device layers 1210 and 1212, the doped material 302 is used as the sacrificial material. The doped material 302 and SiGe 204 are in alternating layers in the isolation region 1214. Including the doped material 302 in the isolation region 1214, and also as sacrificial layers in the device layers 1210 and 1212, may minimize the strain effects described with respect to FIG. 2.

FIG. 12B is a cross-section through a die that includes an active area with a set of stacked transistors formed from the layered materials of FIG. 12A and regions outside of the active area, according to some embodiments of the present disclosure. FIG. 12B may be another alternate embodiment of a cross-section through the plane CC′ of FIG. 4.

FIG. 12B includes the device layers 1210 and 1212, as well as the isolation region 1214 between the device layers 1210 and 1212. FIG. 12B illustrates an active region 1234 that includes the centers of the device layers 1210 and 1212, and, along the edges, two inactive regions 1236a and 1236b. The inactive regions 1236a and 1236b may correspond to the regions of the scribe lines of FIG. 4, i.e., regions near the edges of the die 403.

Each of the inactive regions 1236 includes the layered materials of FIG. 12A. In the device layers 1210 and 1212, the doped material 302 has been removed and replaced with gate stacks, similar to the gate stack illustrated in FIG. 1B. The layers of SiGe 204 in the device layers 1210 and 1212 form nanoribbon channels that are similar to the nanoribbons 120 described with respect to FIG. 1. The SiGe 204 and the gate stacks (including the gate electrode 110 and gate dielectric 112 described above) form transistors within the active region 1234 of the two device layers 1210 and 1212. In the active region 1234 of the isolation region 1214, the doped material 302 and SiGe 204 have been removed and replaced with a dielectric material 504.

In the device layers 1210 and 1212, the SiGe 204 channels in the active region 1234 are aligned with the layers of SiGe 204 in the inactive regions 1236. In this example, a portion of the layers of the doped material 302 in the inactive regions 1236 are aligned with transistors in the device layer 1210 (and, in particular, aligned with portions of the gate stack); another portion of the layers of the doped material 302 in the inactive regions 1236 are aligned with transistors in the device layer 1212 (and, in particular, aligned with portions of the gate stack). The layers of the doped material 302 and SiGe 204 in the inactive region 1236 are aligned with the dielectric material 504 in the isolation region 1214.

FIG. 12B further includes a front side metallization stack 1220 over the device layer 1212 and a back side metallization stack 1222 under the device layer 1210. The front side metallization stack 1220 and back side metallization stack 1222 are similar to the metallization stack 820 and 822 of FIG. 8B.

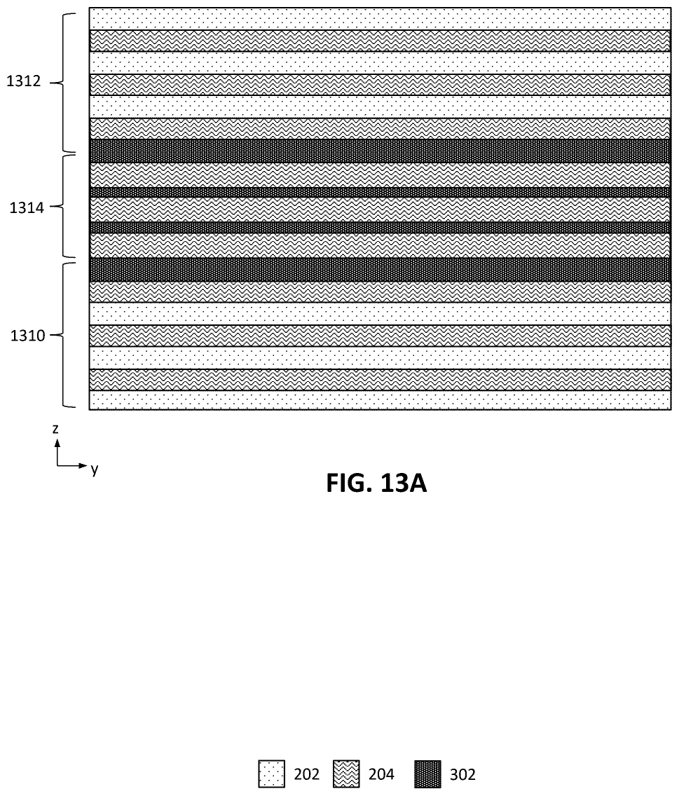

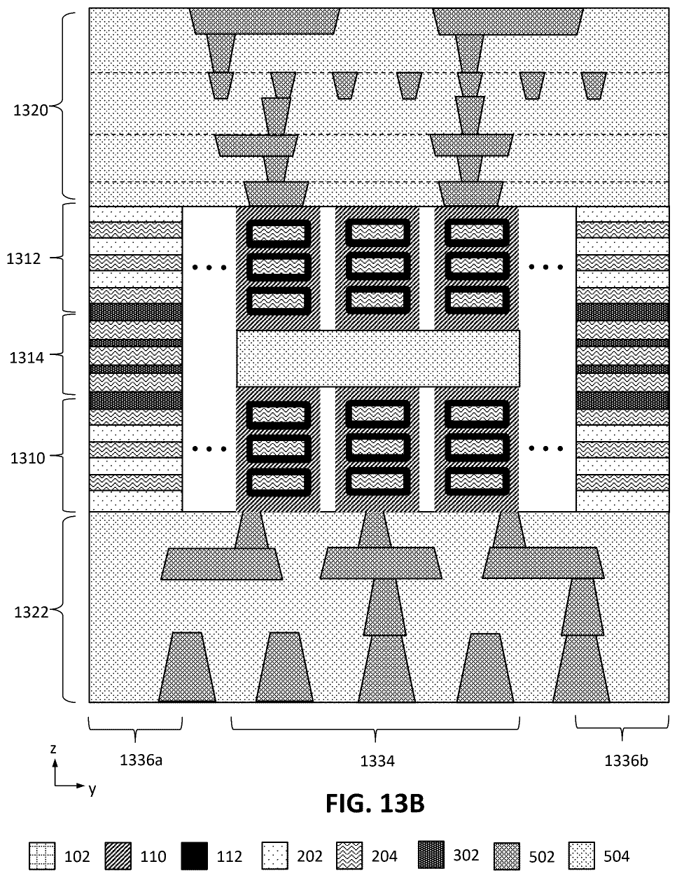

FIG. 13A is a cross-section of alternating layers of a semiconductor channel material, layers of a sacrificial material, and layers of a doped sacrificial material that may be used for forming stacked nanoribbon transistors, according to some embodiments of the present disclosure.

FIG. 13A illustrates layers of SiGe 204 and sacrificial layers of Si 202 and the doped material 302 (which may be doped silicon, as described above). As in prior examples, the layers may be formed over a support structure, e.g., the support structure 102. The layers of SiGe 204 may be used to form nanoribbon channels, while layers of Si 202 and the doped material 302 are sacrificial layers that are removed during fabrication.

FIG. 13A includes two device layers 1310 and 1312 and an isolation region 1314 between the device layers 1310 and 1312. In the isolation region 1314, the layers of the doped material 302 are thinner than the layers of the doped material 302 in the device layers 1310 and 1312, while layers of the SiGe 204 in the isolation region 1314 have the same or similar thickness to layers of SiGe in the device layers 1310 and 1312. In other embodiments, in the isolation region 1314, the layers of SiGe 204 may be relatively thin, e.g., thinner than the layers of SiGe 204 in the device layers 1310 and 1312.

In the device layers 1310 and 1312, the Si 202 is used as the sacrificial material. The doped material 302 and Si 202 are in alternating layers in the isolation region 1314. Including the doped material 302 in the isolation region 1314, but not in the device layers 1310 and 1312, may help prevent or reduce diffusion of the dopant into the channel material, i.e., the layers of SiGe 204 in the device layers 1310 and 1312. In this example, the uppermost layer of doped material 302 is adjacent to a layer of SiGe 204 in the device layer 1312, and the lowermost layer of the doped material 302 is adjacent to a layer of SiGe 204 in the device layer 1310. In other embodiments, these two layers of doped material 302 may be replaced with layers of Si 202, to reduce the risk of diffusion. On the other hand, including less of the doped material 302 within the layers may increase the amount of strain relaxation.

FIG. 13B is a cross-section through a die that includes an active area with a set of stacked transistors formed from the layered materials of FIG. 13A and regions outside of the active area, according to some embodiments of the present disclosure. FIG. 13B may be another alternate embodiment of a cross-section through the plane CC′ of FIG. 4.

FIG. 13B includes the device layers 1310 and 1312, as well as the isolation region 1314 between the device layers 1310 and 1312. FIG. 13B illustrates an active region 1334 that includes the centers of the device layers 1310 and 1312, and, along the edges, two inactive regions 1336a and 1336b. The inactive regions 1336a and 1336b may correspond to the regions of the scribe lines of FIG. 4, i.e., regions near the edges of the die 403.

Each of the inactive regions 1336 includes the layered materials of FIG. 13A. In the device layers 1310 and 1312, the Si 202 has been removed and replaced with gate stacks, similar to the gate stack illustrated in FIG. 1B. The layers of SiGe 204 in the device layers 1310 and 1312 form nanoribbon channels that are similar to the nanoribbons 120 described with respect to FIG. 1. The SiGe 204 and the gate stacks (including the gate electrode 110 and gate dielectric 112 described above) form transistors within the active region 1334 of the two device layers 1310 and 1312. In the active region 1334 of the isolation region 1314, the doped material 302 and SiGe 204 have been removed and replaced with a dielectric material 504.

In the device layers 1310 and 1312, the SiGe 204 channels in the active region 1334 are aligned with the layers of SiGe 204 in the inactive regions 1336. In this example, a portion of the layers of the Si 202 in the inactive regions 1336 are aligned with transistors in the device layer 1310 (and, in particular, aligned with portions of the gate stack); another portion of the layers of the Si 202 in the inactive regions 1336 are aligned with transistors in the device layer 1312 (and, in particular, aligned with portions of the gate stack). The layers of the doped material 302 and SiGe 204 in the inactive region 1336 are aligned with the dielectric material 504 in the isolation region 1314.

FIG. 13B further includes a front side metallization stack 1320 over the device layer 1312 and a back side metallization stack 1322 under the device layer 1310. The front side metallization stack 1320 and back side metallization stack 1322 are similar to the metallization stack 820 and 822 of FIG. 8B.

### Example Devices

The nanoribbon transistors formed from stacked materials with a strain dopant disclosed herein may be included in any suitable electronic device. FIGS. 14-17 illustrate various examples of apparatuses that may include the GAA transistors disclosed herein, which may have been fabricated using the processes disclosed herein.

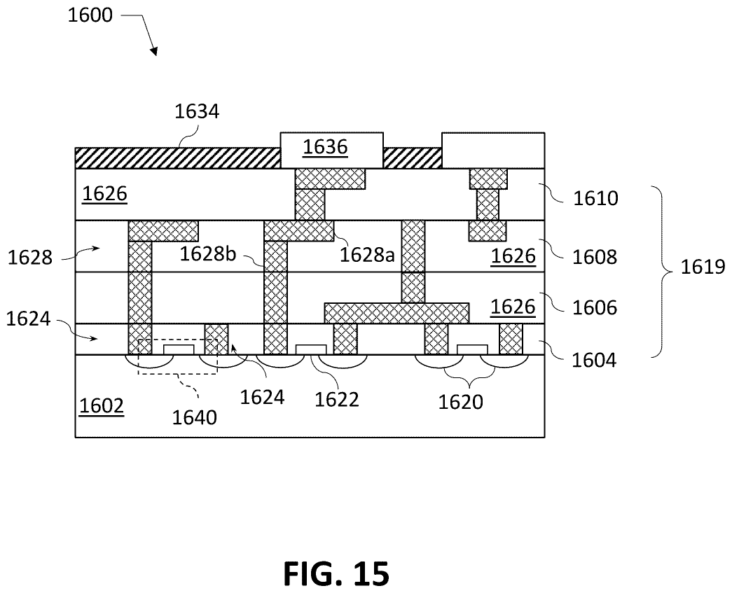

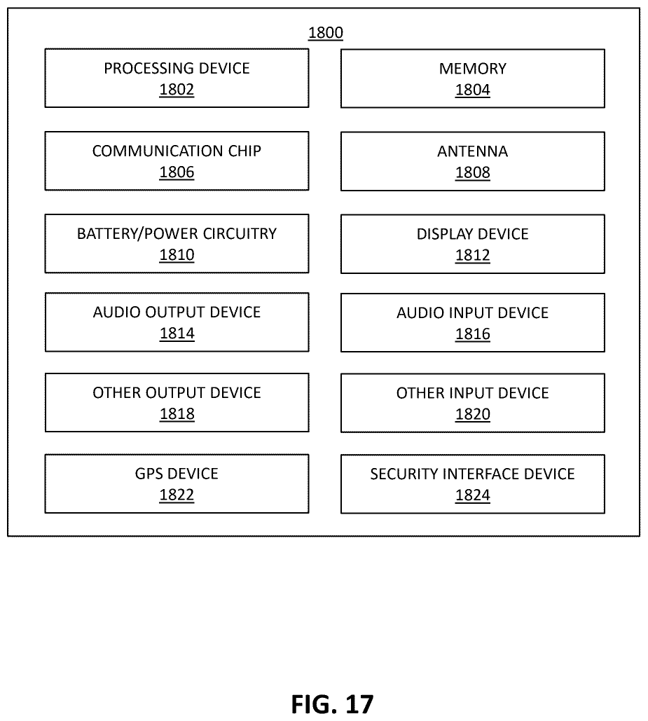

FIGS. 14A and 14B are top views of a wafer and dies that include one or more IC structures including one or more nanoribbon transistors formed from stacked materials with a strain dopant in accordance with any of the embodiments disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC structure (e.g., the IC structures as shown in any of FIGS. 2-14, or any further embodiments of the IC structures described herein). After the fabrication of the semiconductor product is complete (e.g., after manufacture of one or more IC structures with one or more of the transistors as described herein, included in a particular electronic component, e.g., in a transistor or in a memory device), the wafer 1500 may undergo a singulation process in which each of the dies 1502 is separated from one another to provide discrete “chips” of the semiconductor product. In particular, devices that include one or more of the transistors as disclosed herein may take the form of the wafer 1500 (e.g., not singulated) or the form of the die 1502 (e.g., singulated). The die 1502 may include one or more transistors (e.g., one or more of the transistors 1640 of FIG. 15, discussed below) and/or supporting circuitry to route electrical signals to the transistors, as well as any other IC components (e.g., one or more of the non-planar transistors described herein). In some embodiments, the wafer 1500 or the die 1502 may include a memory device (e.g., an SRAM device), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 17) or other logic that is configured to store information in the memory devices or execute instructions stored in the memory array.

FIG. 15 is a cross-sectional side view of an IC device 1600 that may include one or more nanoribbon transistors formed from stacked materials with a strain dopant in accordance with any of the embodiments disclosed herein. The IC device 1600 may be formed on a substrate 1602 (e.g., the wafer 1500 of FIG. 14A) and may be included in a die (e.g., the die 1502 of FIG. 14B). The substrate 1602 may be any substrate as described herein. The substrate 1602 may be part of a singulated die (e.g., the dies 1502 of FIG. 14B) or a wafer (e.g., the wafer 1500 of FIG. 14A).

The IC device 1600 may include one or more device layers 1604 disposed on the substrate 1602. The device layer 1604 may include features of one or more transistors 1640 (e.g., metal-oxide-semiconductor field-effect transistors (MOSFETs)) formed on the substrate 1602. The device layer 1604 may include, for example, one or more source and/or drain (S/D) regions 1620, a gate 1622 to control current flow in the transistors 1640 between the S/D regions 1620, and one or more S/D contacts 1624 to route electrical signals to/from the S/D regions 1620. The transistors 1640 may include additional features not depicted for the sake of clarity, such as device isolation regions, gate contacts, and the like. The transistors 1640 are not limited to the type and configuration depicted in FIG. 15 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 1640 may include a gate 1622 formed of at least two layers, a gate electrode layer and a gate dielectric layer.

The gate electrode layer may be formed on the gate interconnect support layer and may consist of at least one P-type workfunction metal or N-type workfunction metal, depending on whether the transistor is to be a PMOS or an NMOS transistor, respectively. In some implementations, the gate electrode layer may consist of a stack of two or more metal layers, where one or more metal layers are workfunction metal layers and at least one metal layer is a fill metal layer. Further metal layers may be included for other purposes, such as a barrier layer or/and an adhesion layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 electron Volts (eV) and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, aluminum carbide, tungsten, tungsten carbide. An N-type metal layer will enable the formation of an NMOS gate electrode with a workfunction that is between about 3.9 eV and about 4.2 eV.

In some embodiments, when viewed as a cross-section of the transistor 1640 along the source-channel-drain direction, the gate electrode may be formed as a U-shaped structure that includes a bottom portion substantially parallel to the surface of the substrate and two sidewall portions that are substantially perpendicular to the top surface of the substrate. In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode may be implemented as a combination of U-shaped structures and planar, non-U-shaped structures. For example, the gate electrode may be implemented as one or more U-shaped metal layers formed atop one or more planar, non-U-shaped layers. In some embodiments, the gate electrode may consist of a V-shaped structure (e.g., when a fin of a FinFET transistor does not have a “flat” upper surface, but instead has a rounded peak).

Generally, the gate dielectric layer of a transistor 1640 may include one layer or a stack of layers, and the one or more layers may include silicon oxide, silicon dioxide, and/or a high-k dielectric material. The high-k dielectric material included in the gate dielectric layer of the transistor 1640 may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The IC device 1600 may include one or more nanoribbon transistors formed from stacked materials with a strain dopant at any suitable location in the IC device 1600.

The S/D regions 1620 may be formed within the substrate 1602 adjacent to the gate 1622 of each transistor 1640, using any suitable processes known in the art. For example, the S/D regions 1620 may be formed using either an implantation/diffusion process or a deposition process. In the former process, dopants such as boron, aluminum, antimony, phosphorous, or arsenic may be ion-implanted into the substrate 1602 to form the S/D regions 1620. An annealing process that activates the dopants and causes them to diffuse farther into the substrate 1602 may follow the ion implantation process. In the latter process, an epitaxial deposition process may provide material that is used to fabricate the S/D regions 1620. In some implementations, the S/D regions 1620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1620 may be formed using one or more alternate semiconductor materials such as germanium or a group III-V material or alloy. In further embodiments, one or more layers of metal and/or metal alloys may be used to form the S/D regions 1620. In some embodiments, an etch process may be performed before the epitaxial deposition to create recesses in the substrate 1602 in which the material for the S/D regions 1620 is deposited.

Electrical signals, such as power and/or input/output (I/O) signals, may be routed to and/or from the transistors 1640 of the device layer 1604 through one or more interconnect layers disposed on the device layer 1604 (illustrated in FIG. 15 as interconnect layers 1606-1610). For example, electrically conductive features of the device layer 1604 (e.g., the gate 1622 and the S/D contacts 1624) may be electrically coupled with the interconnect structures 1628 of the interconnect layers 1606-1610. The one or more interconnect layers 1606-1610 may form an ILD stack 1619 of the IC device 1600.

The interconnect structures 1628 may be arranged within the interconnect layers 1606-1610 to route electrical signals according to a wide variety of designs (in particular, the arrangement is not limited to the particular configuration of interconnect structures 1628 depicted in FIG. 15). Although a particular number of interconnect layers 1606-1610 is depicted in FIG. 15, embodiments of the present disclosure include IC devices having more or fewer interconnect layers than depicted.

In some embodiments, the interconnect structures 1628 may include trench contact structures 1628a (sometimes referred to as “lines”) and/or via structures 1628b (sometimes referred to as “holes”) filled with an electrically conductive material such as a metal. The trench contact structures 1628a may be arranged to route electrical signals in a direction of a plane that is substantially parallel with a surface of the substrate 1602 upon which the device layer 1604 is formed. For example, the trench contact structures 1628a may route electrical signals in a direction in and out of the page from the perspective of FIG. 15. The via structures 1628b may be arranged to route electrical signals in a direction of a plane that is substantially perpendicular to the surface of the substrate 1602 upon which the device layer 1604 is formed. In some embodiments, the via structures 1628b may electrically couple trench contact structures 1628a of different interconnect layers 1606-1610 together.

The interconnect layers 1606-1610 may include a dielectric material 1626 disposed between the interconnect structures 1628, as shown in FIG. 15. The dielectric material 1626 may take the form of any of the embodiments of the dielectric material provided between the interconnects of the IC structures disclosed herein.

In some embodiments, the dielectric material 1626 disposed between the interconnect structures 1628 in different ones of the interconnect layers 1606-1610 may have different compositions. In other embodiments, the composition of the dielectric material 1626 between different interconnect layers 1606-1610 may be the same.

A first interconnect layer 1606 (referred to as Metal 1 or “M1”) may be formed directly on the device layer 1604. In some embodiments, the first interconnect layer 1606 may include trench contact structures 1628a and/or via structures 1628b, as shown. The trench contact structures 1628a of the first interconnect layer 1606 may be coupled with contacts (e.g., the S/D contacts 1624) of the device layer 1604.

A second interconnect layer 1608 (referred to as Metal 2 or “M2”) may be formed directly on the first interconnect layer 1606. In some embodiments, the second interconnect layer 1608 may include via structures 1628b to couple the trench contact structures 1628a of the second interconnect layer 1608 with the trench contact structures 1628a of the first interconnect layer 1606. Although the trench contact structures 1628a and the via structures 1628b are structurally delineated with a line within each interconnect layer (e.g., within the second interconnect layer 1608) for the sake of clarity, the trench contact structures 1628a and the via structures 1628b may be structurally and/or materially contiguous (e.g., simultaneously filled during a dual-damascene process) in some embodiments.

A third interconnect layer 1610 (referred to as Metal 3 or “M3”) (and additional interconnect layers, as desired) may be formed in succession on the second interconnect layer 1608 according to similar techniques and configurations described in connection with the second interconnect layer 1608 or the first interconnect layer 1606.

The IC device 1600 may include a solder resist material 1634 (e.g., polyimide or similar material) and one or more bond pads 1636 formed on the interconnect layers 1606-1610. The bond pads 1636 may be electrically coupled with the interconnect structures 1628 and configured to route the electrical signals of the transistor(s) 1640 to other external devices. For example, solder bonds may be formed on the one or more bond pads 1636 to mechanically and/or electrically couple a chip including the IC device 1600 with another component (e.g., a circuit board). The IC device 1600 may have other alternative configurations to route the electrical signals from the interconnect layers 1606-1610 than depicted in other embodiments. For example, the bond pads 1636 may be replaced by or may further include other analogous features (e.g., posts) that route the electrical signals to external components.

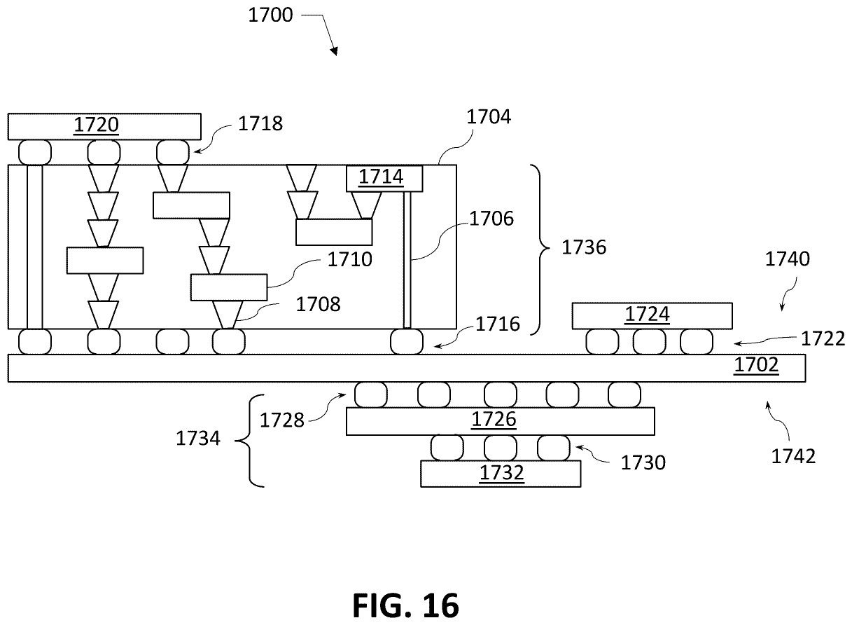

FIG. 16 is a cross-sectional side view of an IC device assembly 1700 that may include components having or being associated with (e.g., being electrically connected by means of) one or more nanoribbon transistors formed from stacked materials with a strain dopant in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. In particular, any suitable ones of the components of the IC device assembly 1700 may include one or more of the non-planar transistors disclosed herein.

In some embodiments, the circuit board 1702 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 16 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702 and may include solder balls (as shown in FIG. 16), male and female portions of a socket, an adhesive, an underfill material, and/or any other suitable electrical and/or mechanical coupling structure.

The package-on-interposer structure 1736 may include an IC package 1720 coupled to an interposer 1704 by coupling components 1718. The coupling components 1718 may take any suitable form for the application, such as the forms discussed above with reference to the coupling components 1716. Although a single IC package 1720 is shown in FIG. 16, multiple IC packages may be coupled to the interposer 1704; indeed, additional interposers may be coupled to the interposer 1704. The interposer 1704 may provide an intervening substrate used to bridge the circuit board 1702 and the IC package 1720. The IC package 1720 may be or include, for example, a die (the die 1502 of FIG. 14B), an IC device (e.g., the IC device 1600 of FIG. 15), or any other suitable component. In some embodiments, the IC package 1720 may include one or more nanoribbon transistors formed from stacked materials with a strain dopant, as described herein. Generally, the interposer 1704 may spread a connection to a wider pitch or reroute a connection to a different connection. For example, the interposer 1704 may couple the IC package 1720 (e.g., a die) to a ball grid array (BGA) of the coupling components 1716 for coupling to the circuit board 1702. In the embodiment illustrated in FIG. 16, the IC package 1720 and the circuit board 1702 are attached to opposing sides of the interposer 1704; in other embodiments, the IC package 1720 and the circuit board 1702 may be attached to a same side of the interposer 1704. In some embodiments, three or more components may be interconnected by way of the interposer 1704.

The interposer 1704 may be formed of an epoxy resin, a fiberglass-reinforced epoxy resin, a ceramic material, or a polymer material such as polyimide. In some implementations, the interposer 1704 may be formed of alternate rigid or flexible materials that may include the same materials described above for use in a semiconductor substrate, such as silicon, germanium, and other group III-V and group IV materials. The interposer 1704 may include metal interconnects 1708 and vias 1710, including but not limited to TSVs 1706. The interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency (RF) devices, power amplifiers, power management devices, antennas, arrays, sensors, and microelectromechanical systems (MEMS) devices may also be formed on the interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 16 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 17 is a block diagram of an example computing device 1800 that may include one or more nanoribbon transistors formed from stacked materials with a strain dopant in accordance with any of the embodiments disclosed herein. For example, any suitable ones of the components of the computing device 1800 may include a die (e.g., the die 1502 (FIG. 14B)) having one or more nanoribbon transistors formed from stacked materials with a strain dopant. Any one or more of the components of the computing device 1800 may include, or be included in, an IC device 1600 (FIG. 15). Any one or more of the components of the computing device 1800 may include, or be included in, an IC device assembly 1700 (FIG. 16).

A number of components are illustrated in FIG. 17 as included in the computing device 1800, but any one or more of these components may be omitted or duplicated, as suitable for the application. In some embodiments, some or all of the components included in the computing device 1800 may be attached to one or more motherboards. In some embodiments, some or all of these components are fabricated onto a single system-on-a-chip (SoC) die.

Additionally, in various embodiments, the computing device 1800 may not include one or more of the components illustrated in FIG. 17, but the computing device 1800 may include interface circuitry for coupling to the one or more components. For example, the computing device 1800 may not include a display device 1812, but may include display device interface circuitry (e.g., a connector and driver circuitry) to which a display device 1812 may be coupled. In another set of examples, the computing device 1800 may not include an audio input device 1816 or an audio output device 1814, but may include audio input or output device interface circuitry (e.g., connectors and supporting circuitry) to which an audio input device 1816 or audio output device 1814 may be coupled.

The computing device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The computing device 1800 may include a memory 1804, which may itself include one or more memory devices such as volatile memory (e.g., dynamic random access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic random access memory (eDRAM) or spin transfer torque magnetic random-access memory (STT-MRAM).

In some embodiments, the computing device 1800 may include a communication chip 1806 (e.g., one or more communication chips). For example, the communication chip 1806 may be configured for managing wireless communications for the transfer of data to and from the computing device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1806 may implement any of a number of wireless standards or protocols, including but not limited to Institute for Electrical and Electronic Engineers (IEEE) standards including Wi-Fi (IEEE 1402.11 family), IEEE 1402.18 standards (e.g., IEEE 1402.18-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 1402.18 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 1402.18 standards. The communication chip 1806 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1806 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1806 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1806 may operate in accordance with other wireless protocols in other embodiments. The computing device 1800 may include an antenna 1808 to facilitate wireless communications and/or to receive other wireless communications (such as AM or FM radio transmissions).

In some embodiments, the communication chip 1806 may manage wired communications, such as electrical, optical, or any other suitable communication protocols (e.g., the Ethernet). As noted above, the communication chip 1806 may include multiple communication chips. For instance, a first communication chip 1806 may be dedicated to shorter-range wireless communications such as Wi-Fi or Bluetooth, and a second communication chip 1806 may be dedicated to longer-range wireless communications such as GPS, EDGE, GPRS, CDMA, WiMAX, LTE, EV-DO, or others. In some embodiments, a first communication chip 1806 may be dedicated to wireless communications, and a second communication chip 1806 may be dedicated to wired communications.

The computing device 1800 may include a battery/power circuitry 1810. The battery/power circuitry 1810 may include one or more energy storage devices (e.g., batteries or capacitors) and/or circuitry for coupling components of the computing device 1800 to an energy source separate from the computing device 1800 (e.g., AC line power).

The computing device 1800 may include a display device 1812 (or corresponding interface circuitry, as discussed above). The display device 1812 may include any visual indicators, such as a heads-up display, a computer monitor, a projector, a touchscreen display, a liquid crystal display (LCD), a light-emitting diode display, or a flat panel display, for example.

The computing device 1800 may include an audio output device 1814 (or corresponding interface circuitry, as discussed above). The audio output device 1814 may include any device that generates an audible indicator, such as speakers, headsets, or earbuds, for example.

The computing device 1800 may include an audio input device 1816 (or corresponding interface circuitry, as discussed above). The audio input device 1816 may include any device that generates a signal representative of a sound, such as microphones, microphone arrays, or digital instruments (e.g., instruments having a musical instrument digital interface (MIDI) output).

The computing device 1800 may include another output device 1818 (or corresponding interface circuitry, as discussed above). Examples of the other output device 1818 may include an audio codec, a video codec, a printer, a wired or wireless transmitter for providing information to other devices, or an additional storage device.

The computing device 1800 may include another input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 1800 may include a global positioning system (GPS) device 1822 (or corresponding interface circuitry, as discussed above). The GPS device 1822 may be in communication with a satellite-based system and may receive a location of the computing device 1800, as known in the art.

The computing device 1800 may include a security interface device 1824. The security interface device 1824 may include any device that provides security features for the computing device 1800 or for any individual components therein (e.g., for the processing device 1802 or for the memory 1804). Examples of security features may include authorization, access to digital certificates, access to items in keychains, etc. Examples of the security interface device 1824 may include a software firewall, a hardware firewall, an antivirus, a content filtering device, or an intrusion detection device.

The computing device 1800 may have any desired form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 1800 may be any other electronic device that processes data.

### Select Examples

The following paragraphs provide various examples of the embodiments disclosed herein.

Example 1 provides a device including a first region including a plurality of transistors, one of the transistors including a plurality of channel regions including germanium; and a second region including a stack of materials, the stack of materials including a first plurality of layers, the first plurality of layers including germanium; and a second plurality of layers, at least one of the second plurality of layers between a pair of the first plurality of layers, and the second plurality of layers including a material that includes silicon and a dopant, the dopant selected from carbon, arsenic, boron, and phosphorus.

Example 2 provides the device of example 1, where one of the plurality of channel regions is aligned with one of the first plurality of layers.

Example 3 provides the device of example 1 or 2, where the second region of the device does not include circuitry.

Example 4 provides the device of any of examples 1-3, where the device is a die, and the second region of the device is at an edge of the die.

Example 5 provides the device of any of examples 1-4, where the dopant includes at least 0.5% by weight of the material of the second plurality of layers.

Example 6 provides the device of any of examples 1-5, where the dopant includes no more than 5% by weight of the material of the second plurality of layers.

Example 7 provides the device of any of examples 1-6, where the plurality of channel regions and the first plurality of layers further include silicon.

Example 8 provides a device including a first region including a plurality of transistors, one of the transistors including a plurality of channel regions including silicon; and a second region including a stack of materials, the stack of materials including a first plurality of layers, the first plurality of layers including silicon; a second plurality of layers, at least one of the second plurality of layers between a pair of the first plurality of layers, the second plurality of layers including germanium; and a cap layer over the first plurality of layers and the second plurality of layers, the cap layer including a material that includes silicon and a dopant, the dopant selected from carbon, arsenic, boron, and phosphorus.

Example 9 provides the device of example 8, where one of the plurality of channel regions is aligned with one of the first plurality of layers.

Example 10 provides the device of example 8 or 9, where the cap layer and the one of the transistors are over a substrate, and the cap layer is a greater distance from the substrate than an uppermost one of the plurality of channel regions.

Example 11 provides the device of any of examples 8-10, where the plurality of channel regions do not include the dopant.

Example 12 provides the device of any of examples 8-11, where the device is a die, and the second region of the device is at an edge of the die.

Example 13 provides an integrated circuit (IC) device including a first region including a first device layer including a first transistor, the first transistor including a first stack of nanoribbons; a second device layer over the first device layer, the second device layer including a second transistor, the second transistor including a second stack of nanoribbons; and an isolation region between the first device layer and the second device layer; and a second region including a stack of materials, the stack of materials including a first plurality of layers aligned with the first stack of nanoribbons; a second plurality of layers aligned with the second stack of nanoribbons; and a doped layer including a material that includes at least one dopant, the dopant selected from carbon, arsenic, boron, and phosphorus.

Example 14 provides the IC device of example 13, where the material of the doped layer further includes at least one of silicon and germanium.

Example 15 provides the IC device of example 13 or 14, where the doped layer is between the first plurality of layers and the second plurality of layers, and the doped layer is aligned with at least a portion of the isolation region.

Example 16 provides the IC device of example 15, where the doped layer has a first thickness, the nanoribbons in the first stack have a second thickness, the second thickness greater than the first thickness.

Example 17 provides the IC device of example 15 or 16, where the doped layer is a first doped layer, and the second region of the IC device further includes a second doped layer above the first doped layer, the second doped layer aligned with a different portion of the isolation region.

Example 18 provides the IC device of example 13 or 14, where the doped layer is over the second plurality of layers.

Example 19 provides the IC device of example 13 or 14, where the doped layer is between a pair of layers in the first plurality of layers.

Example 20 provides the IC device of example 19, further including a second doped layer between a second pair of layers in the second plurality of layers.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

What is claimed is:

1. A device comprising:
a first region comprising a plurality of transistors, one of the plurality of transistors comprising a plurality of channel regions comprising germanium; and
a second region comprising a stack of materials, the stack of materials comprising:
a first plurality of layers, the first plurality of layers comprising germanium; and
a second plurality of layers, at least one of the second plurality of layers between a pair of the first plurality of layers, and the second plurality of layers comprising a material that includes silicon and a dopant, the dopant selected from carbon, arsenic, boron, and phosphorus.

2. The device of claim 1, wherein one of the plurality of channel regions is aligned with one of the first plurality of layers.

3. The device of claim 1, wherein the second region of the device does not include circuitry.

4. The device of claim 1, wherein the device is a die, and the second region of the device is at an edge of the die.

5. The device of claim 1, wherein the dopant comprises at least 0.5% by weight of the material of the second plurality of layers.

6. The device of claim 1, wherein the dopant comprises no more than 5% by weight of the material of the second plurality of layers.

7. The device of claim 1, wherein the plurality of channel regions and the first plurality of layers further comprise silicon.

8. A device comprising:
a first region comprising a plurality of transistors, one of the plurality of transistors comprising a plurality of channel regions comprising silicon; and
a second region comprising a stack of materials, the stack of materials comprising:
a first plurality of layers, the first plurality of layers comprising silicon;
a second plurality of layers, at least one of the second plurality of layers between a pair of the first plurality of layers, the second plurality of layers comprising germanium; and
a cap layer over the first plurality of layers and the second plurality of layers, the cap layer comprising a material that includes silicon and a dopant, the dopant selected from carbon, arsenic, boron, and phosphorus.

9. The device of claim 8, wherein one of the plurality of channel regions is aligned with one of the first plurality of layers.

10. The device of claim 8, wherein the cap layer and the one of the plurality of transistors are over a substrate, and the cap layer is a greater distance from the substrate than an uppermost one of the plurality of channel regions.

11. The device of claim 8, wherein the plurality of channel regions do not include the dopant.

12. The device of claim 8, wherein the device is a die, and the second region of the device is at an edge of the die.

13. An integrated circuit (IC) device comprising:
a first region comprising:
a first device layer comprising a first transistor, the first transistor comprising a first stack of nanoribbons;
a second device layer over the first device layer, the second device layer comprising a second transistor, the second transistor comprising a second stack of nanoribbons; and
an isolation region between the first device layer and the second device layer; and
a second region comprising a stack of materials, the stack of materials comprising:
a first plurality of layers aligned with the first stack of nanoribbons;
a second plurality of layers aligned with the second stack of nanoribbons; and
a doped layer comprising a material that includes at least one dopant, the dopant selected from carbon, arsenic, boron, and phosphorus.

14. The IC device of claim 13, wherein the material of the doped layer further comprises at least one of silicon and germanium.

15. The IC device of claim 13, wherein the doped layer is between the first plurality of layers and the second plurality of layers, and the doped layer is aligned with at least a portion of the isolation region.

16. The IC device of claim 15, wherein the doped layer has a first thickness, the nanoribbons in the first stack of nanoribbons have a second thickness, the second thickness greater than the first thickness.

17. The IC device of claim 15, wherein the doped layer is a first doped layer, and the second region of the IC device further comprises a second doped layer above the first doped layer, the second doped layer aligned with a different portion of the isolation region.

18. The IC device of claim 13, wherein the doped layer is over the second plurality of layers.

19. The IC device of claim 13, wherein the doped layer is between a pair of layers in the first plurality of layers.

20. The IC device of claim 19, further comprising a second doped layer between a second pair of layers in the second plurality of layers.
